(19) United States
(12) Patent Application Publication
(10) Pub. No.: US 2024/0027380 A1
(43) Pub. Date: Jan. 25, 2024

(54) NONINVASIVE DETECTION OF COUNTERFEIT AND SUBSTANDARD VACCINES AND BIOTHERAPEUTICS

(71) Applicant: UNIVERSITY OF MARYLAND, BALTIMORE, Baltimore, MD (US)

(72) Inventors: Yihua (Bruce) YU, Ellicott City, MD (US); Marc TARABAN, North Potomac, MD (US); Katharine T. BRIGGS, Germantown, MD (US)

(21) Appl. No.: 18/356,554

(22) Filed: Jul. 21, 2023

Related U.S. Application Data
(60) Provisional application No. 63/369,333, filed on Jul. 25, 2022.

(51) Int. Cl. G01N 24/08; G01N 15/04

(52) U.S. Cl. CPC G01N 24/082; G01N 15/04

(57) ABSTRACT

Methods for non-invasively identifying substandard or counterfeit products, e.g., vaccines, using nuclear magnetic resonance. The methods provide manufacturers with new approaches to identify parameters to assist users with the identification of substandard or counterfeit products.

### CROSS REFERENCE TO RELATED APPLICATIONS

This application is filed under the provisions of 35 U.S.C. § 111(a) and claims priority to U.S. Provisional Patent Application No. 63/369,333 filed on Jul. 25, 2022 in the name of Yihua (Bruce) Y U, et al., and entitled “Noninvasive Detection of Counterfeit and Substandard Vaccines and Biotherapeutics,” which is hereby incorporated by reference herein in its entirety.

### STATEMENT OF FEDERALLY SPONSORED RESEARCH

This invention was made with government support under Grant Number 70NANB21H085 awarded by the National Institute for Innovation in Manufacturing Biopharmaceuticals. The government has certain rights in the invention.

### FIELD

The present invention relates to methods for non-invasively identifying substandard or counterfeit products, e.g., vaccines, using nuclear magnetic resonance. The methods described herein further provide manufacturers with new approaches to identify parameters to assist users with the identification of substandard or counterfeit products.

### DESCRIPTION OF THE RELATED ART

Counterfeit and substandard vaccines and biotherapeutics affect mainly regions where medical and distribution infrastructures are inadequate. Domestically, such regions may be remote rural areas and impoverished cities/towns while internationally such regions may be low and middle income countries. In the fight against global pandemics, ensuring equity in medication quality throughout the world is vital.

There is a need for a fast and reliable technique to identify parameters useful to non-invasively identify counterfeit and substandard products by end users with minimal training using instruments that can easily be deployed in the field. Towards that end, the present invention relates to methods of using the transverse relaxation rate of a solvent NMR signal or the longitudinal relaxation rate of a solvent NMR signal to provide the pharmaceutical/biotech industry professionals, law enforcement agencies and other users with more useful parameters to identify counterfeit and substandard products. Advantageously, the methods can be performed noninvasively, without the requirement of opening the vial and/or without destruction of the valuable products contained therein.

### SUMMARY

In a first aspect, a method of using multi-variate NMR to identify a substandard or counterfeit product is described, said method comprising:
identifying a preferred inter-pulse delay (τ) value for a transverse relaxation rate of solvent R₂ measurement, by:
   inserting a first vial comprising a product in a nuclear magnetic resonance (NMR) instrument, wherein the product in the first vial is not substandard or a counterfeit;
   varying pulse sequence inter-pulse delay (τ) values from x ms to y ms in increments of z ms, wherein z could be any value, but preferably <x and cannot be >y, at a set temperature, and measuring the transverse relaxation rate of solvent R₂ at each τ value, thereby obtaining a first fingerprint for the product in the first vial;
   inserting a second vial comprising a product suspected to be substandard or counterfeit in the NMR instrument;
   varying the same pulse sequence inter-pulse delay (τ) values of x, y, and z, at the same set temperature, and measuring the transverse relaxation rate of solvent R₂ at each τ value, thereby obtaining a second fingerprint for the product in the second vial;
   identifying the preferred τ value by identifying a τ value where |R₂ (first vial)−R₂ (second vial)| is the greatest between x ms and y ms,
wherein the transverse relaxation rate of solvent R₂ should be measured at the preferred τ value to identify a vial comprising a substandard or counterfeit of the product in the first vial. In some embodiments, the solvent is water and the transverse relaxation rate of water R₂(¹H₂O) is measured. In some embodiments, the value of x is 1 or less, preferably 0.5. In some embodiments, y is 10 or more, preferably 10. In some embodiments, z is less than x and y/z is 20 or greater, preferably 0.25. In some embodiments, R₂ is measured without opening the first or second vials or otherwise accessing the contents of the first or second vials. In some embodiments, the first fingerprint and the second fingerprint are obtained at substantially the same temperature. In some embodiments, the first fingerprint and the second fingerprint are obtained at substantially the same magnetic field strength. In some embodiments, the method further comprises measuring the transverse relaxation rate of solvent R₂ of a new vial in a lot comprising the second vial, at the preferred τ value, wherein the product in the new vial is suspected of being a substandard or counterfeit of the product in the first vial. A non-transitory computer-readable storage medium is also described, storing a computer program thereon which, when run in a computer, causes the computer to carry out the steps of this method.

In another aspect, a method of using multi-variate NMR to identify a substandard or counterfeit product in a lot is described, said method comprising:
inserting a vial comprising a second product in a nuclear magnetic resonance (NMR) instrument, wherein the second product is suspected to be substandard or a counterfeit of a first product;
varying pulse sequence inter-pulse delay (τ) values from x ms to y ms in increments of z ms, wherein z could be any value, but preferably <x and cannot be >y, at a set temperature, and measuring the transverse relaxation rate of solvent R₂ at each τ value, thereby obtaining a second fingerprint for the second product in the vial, wherein the values of x, y, and z are specific to the first product and intended for the identification of a substandard or counterfeit product;
comparing a first fingerprint provided for the first product with the second fingerprint obtained for the second product;
identifying the preferred τ value by identifying a τ value where |R₂ (first product)−R₂ (second second)| is the greatest between x ms and y ms; and
using the preferred τ value when measuring the transverse relaxation rate of solvent R₂ of other vials in the lot,
   wherein a substandard or counterfeit product in the lot is identified when the transverse relaxation rate of solvent R₂ is statistically different than the transverse relaxation rate of solvent R₂ of the first product at the preferred τ value. In some embodiments, the solvent is water and the transverse relaxation rate of water R₂(¹H₂O) is measured. In some embodiments, the value of x is 1 or less, preferably 0.5. In some embodiments, y is 10 or more, preferably 10. In some embodiments, z is less than x and y/z is 20 or greater, preferably 0.25. In some embodiments, R₂ is measured without opening the vial containing the second product or otherwise accessing the contents of said vial. In some embodiments, the first fingerprint and the second fingerprint are obtained at substantially the same temperature. In some embodiments, the first fingerprint and the second fingerprint are obtained at substantially the same magnetic field strength. A non-transitory computer-readable storage medium is also described, storing a computer program thereon which, when run in a computer, causes the computer to carry out the steps of this method.

In still another aspect, a method of using a sedimentation rate to identify a substandard or counterfeit product is described, said method comprising:
measuring a sedimentation rate of a product contained in a first vial using a nuclear magnetic resonance (NMR) instrument, wherein the product in the first vial is not substandard or a counterfeit;
measuring a sedimentation rate of a product contained in a second vial using the NMR instrument, wherein the product in the second vial is suspected to be substandard or counterfeit; and
comparing the sedimentation rate of the product in the first vial and the product in the second vial,
   wherein a substandard or counterfeit product is identified when the sedimentation rate of the product in the second vial is statistically different than the sedimentation rate of the product in the first vial. In some embodiments, the product of the first vial and the second vial is a dispersed suspension. In some embodiments, the product of the first vial and the second vial comprises an aluminum adjuvant. In some embodiments, the method further comprises: fully dispersing the product contained in the first vial, wherein the product is a suspension; inserting the first vial in a nuclear magnetic resonance (NMR) instrument; measuring a transverse relaxation rate of solvent R₂ at a single τ value over time t; and determining the sedimentation rate of the product in the first vial using a sedimentation kinetics profile (R₂(solvent, t)) of the product. In some embodiments, the method further comprises: fully dispersing the product contained in the second vial, wherein the product is a suspension; inserting the second vial in a nuclear magnetic resonance (NMR) instrument; measuring a transverse relaxation rate of solvent R₂ at a single τ value over time t; and determining the sedimentation rate of the product in the second vial using a sedimentation kinetics profile (R₂(solvent, t)) of the product. In some embodiments, the solvent is water and the transverse relaxation rate of water R₂(¹H₂O) is measured. In some embodiments, the sedimentation rate is determined without opening the vial containing the first or second product or otherwise accessing the contents of said vials. In some embodiments, the sedimentations rates are obtained at substantially the same temperature. In some embodiments, the sedimentations rates are obtained at substantially the same magnetic field strength. A non-transitory computer-readable storage medium is also described, storing a computer program thereon which, when run in a computer, causes the computer to carry out the steps of this method.

In another aspect, a method of obtaining a fingerprint of a product contained in a vial is described, said method comprising:

measuring transverse relaxation rate of solvent R₂ over time at two alternating τ-values of a fully dispersed product in said vial, wherein the product is a suspension, and wherein the transverse relaxation rate of solvent R₂ at multiple, alternating τ-values is collected throughout a sedimentation process of the product. In some embodiments, the solvent is water and the transverse relaxation rate of water R₂(¹H₂O) is measured. In some embodiments, the two alternating τ-values can be x ms and y ms, wherein the value of x is 1 or less, and the value of y is 10 or more. A non-transitory computer-readable storage medium is also described, storing a computer program thereon which, when run in a computer, causes the computer to carry out the steps of this method.

In yet another aspect, a method of identifying a substandard or counterfeit product is described, said method comprising:
inserting a first vial comprising a product in a nuclear magnetic resonance (NMR) instrument, wherein the product in the first vial is not substandard or a counterfeit;
measuring transverse relaxation rate of solvent R₂ over time at two alternating τ-values of a fully dispersed product in said first vial, wherein the product is a suspension, and wherein the transverse relaxation rate of solvent R₂ at the alternating τ-values is collected throughout a sedimentation process of the product in the first vial;
inserting a second vial comprising a product in the NMR instrument, wherein the product in the second vial is suspected to be substandard or a counterfeit of the product in the first vial;
measuring transverse relaxation rate of solvent R₂ over time at two alternating τ-values of a fully dispersed product in said second vial, wherein the product is a suspension, and wherein the transverse relaxation rate of solvent R₂ at the alternating τ-values is collected throughout a sedimentation process of the product in the second vial; and
identifying a preferred τ-value by selecting one of the two alternating τ-values where the transverse relaxation rate of solvent R₂ is statistically different;
   wherein a substandard or counterfeit product is identified by measuring the transverse relaxation rate of solvent R₂ of a fully dispersed product in a new vial, at the preferred τ value, wherein the sedimentation rate of the product in the new vial is substantially different than the sedimentation rate of the product in the first vial. In some embodiments, the solvent is water and the transverse relaxation rate of water R₂(¹H₂O) is measured. In some embodiments, the two alternating τ-values can be x ms and y ms, wherein the value of x is 1 or less, and the value of y is 10 or more. In some embodiments, R₂ is measured without opening the vials or otherwise accessing the contents of said vials. In some embodiments, the first and second vials are measured at substantially the same temperature. In some embodiments, the first and second vials are measured at substantially the same magnetic field strength. A non-transitory computer-readable storage medium is also described, storing a computer program thereon which, when run in a computer, causes the computer to carry out the steps of this method.

In still another aspect, a method of identifying a substandard or counterfeit product is described, said method comprising:
inserting a first vial comprising a product in a nuclear magnetic resonance (NMR) instrument, wherein the product in the first vial is not substandard or a counterfeit;
measuring transverse relaxation rate of solvent R₂ over time at multiple τ-values of a fully dispersed product in said first vial, wherein the product is a suspension, and wherein the transverse relaxation rate of solvent R₂ at multiple τ-values is collected throughout a sedimentation process of the product in the first vial;
inserting a second vial comprising a product in the NMR instrument, wherein the product in the second vial is suspected to be substandard or a counterfeit of the product in the first vial;
measuring transverse relaxation rate of solvent R₂ over time at multiple τ-values of a fully dispersed product in said second vial, wherein the product is a suspension, and wherein the transverse relaxation rate of solvent R₂ at multiple τ-values is collected throughout a sedimentation process of the product in the second vial; and
plotting the transverse relaxation rate of solvent R₂ as a function of τ for both the first and second vial to obtain a first fingerprint corresponding to the first vial and a second fingerprint corresponding to the second vial, respectively,
   wherein if the first fingerprint and the second fingerprint are not substantially identical, the product in the second vial is a substandard or counterfeit of the product in the first vial. In some embodiments, the solvent is water and the transverse relaxation rate of water R₂(¹H₂O) is measured. In some embodiments, the multiple τ-values correspond to pulse sequence inter-pulse delay (τ) values from x ms to y ms in increments of z ms, wherein z could be any value, but preferably <x and cannot be >y, at a set temperature. In some embodiments, the value of x is 1 or less, preferably 0.5. In some embodiments, y is 10 or more, preferably 10. In some embodiments, z is less than x and y/z is 20 or greater, preferably 0.25. In some embodiments, R₂ is measured without opening the first or second vials or otherwise accessing the contents of the first or second vials. In some embodiments, the first fingerprint and the second fingerprint are obtained at substantially the same temperature. In some embodiments, the first fingerprint and the second fingerprint are obtained at substantially the same magnetic field strength. A non-transitory computer-readable storage medium is also described, storing a computer program thereon which, when run in a computer, causes the computer to carry out the steps of this method.

Other aspects, features and advantages of the invention will be more fully apparent from the ensuing disclosure and appended claims.

### BRIEF DESCRIPTION OF THE DRAWINGS

FIG. 1A. Comparison of R₂(¹H₂O) values using univariate wNMR for brand name emulsion DIPRIVAN relative to a different emulsion product, INTRALIPID, here the simple counterfeit. The significant difference between the values allows for easy detection of the simple counterfeit.

FIG. 1B. Comparison of R₂(¹H₂O) values using multi-variate wNMR for a simple emulsion counterfeit, INTRALIPID, relative to emulsion drug product, DIPRIVAN.

FIG. 1C. Comparison of R₂(¹H₂O) values using multi-variate wNMR for a sophisticated emulsion counterfeit, PROPOFOL, relative to emulsion drug product, DIPRIVAN.

FIG. 2A. Comparison of R₂(¹H₂O) values for MENACTRA (no adjuvant, 0.5 mL, vial) vaccine with the 0.5 mL of 0.9% NaCl in a sealed vial.

FIG. 2B. Comparison of R₂(¹H₂O) values for TYPHIM VI (no adjuvant, 0.5 mL, syringe) vaccine with the 0.5 mL of 0.9% NaCl in a sealed vial.

FIG. 2C. Comparison of R₂(¹H₂O) values for LANTUS with simple counterfeits (sterile saline in the corresponding pen).

FIG. 2D. Comparison of R₂(¹H₂O) values for BASAGLAR with simple counterfeits (sterile saline in the corresponding pen).

FIG. 2E. Comparison of R₂(¹H₂O) values for NEUPOGEN with simple counterfeits (sterile saline in a sealed vial).

FIG. 2F. Comparison of R₂(¹H₂O) values for GRANIX with simple counterfeits (sterile saline in a sealed vial).

FIG. 2G. Comparison of R₂(¹H₂O) values for NIVESTYM with simple counterfeits (sterile saline in a sealed vial).

FIG. 2H. R₂(¹H₂O) values for 10 pre-filled pens of the insulin drug product LANTUS.

FIG. 2I. R₂(¹H₂O) values for 10 pre-filled pens of the insulin drug product BASAGLAR.

FIG. 2J. R₂(¹H₂O) values for 10 pre-filled pens of the insulin drug product insulin glargine-yfgn.

FIG. 2K. R₂(¹H₂O) values for 10 vials of the filgrastim drug product NEUPOGEN.

FIG. 2L. R₂(¹H₂O) values for 10 vials of the filgrastim drug product NIVESTYM.

FIG. 2M. R₂(¹H₂O) values for 10 vials of the filgrastim drug product GRANIX.

FIG. 2N. τ-Dispersion profiles of R₂(¹H₂O, τ) observed for sterile saline (0.5 mL vial, 0.9% NaCl), and two non-adjuvanted vaccines, MENACTRA and TYPHIM VI. Differences between the profiles enable easy detection of the complex counterfeit.

FIG. 2O. R₂(¹H₂O, τ) dispersion profiles for NEUPOEGN/GRANIX/NIVESTYM innovator/biosimilar/biosimilar set.

FIG. 2P. R₂(¹H₂O, τ) dispersion profiles for GRANIX/SALINE pair. Saline serves as a simple counterfeit for GRANIX.

FIG. 3A. Comparison of R₂(¹H₂O) values for ENGERIX-B before (●) and after heat stress ( [symbol] ); ( [symbol] ) are the unstressed vials, which served as controls.

FIG. 3B. Comparison of R₂(¹H₂O) values for TDVAX before (●) and after heat stress ( [symbol] ); ( [symbol] ) are the unstressed vials, which served as controls.

FIG. 3C: Photos of three vaccines after three exposures to −18° C. All vials numbered 6-10 of each vaccine were exposed to −18° C. three separate times standing upright, each for a duration of 17-22 hours. They were tilted on their sides for the photo to distinguish which vials froze because the labels obstruct the side view. After the third exposure to subzero temperature, DAPTACEL #9 did not freeze, ENGERIX-B all vials froze, and VAQTA, none of the vials froze. Vials were subsequently thawed at 4° C. for at least 1.5 hours prior to T₂ water measurement at 4° C. Vial numbers are marked with a circle if they were frozen after the third exposure to −18° C. The circle is dashed if the vial did not freeze at either the first and/or second exposure to −18° C. Vials that did not freeze have no circle. The bottom right panel shows the front label of Vial 1 (not exposed to −18° C.) and the back label of vial 6 (exposed to −18° C.), illustrating the difficulty distinguishing frozen and unfrozen visually without removing the label. The WHO Shake Test requires labels to be removed, but a children's single dose vaccine is a low volume, only 0.5 mL, which would make it difficult to observe visual differences.

FIG. 3D. R₂(¹H₂O) of vaccine suspensions measured after the third exposure to subzero temperatures (−18° C.). Unstressed vials 1-5 (black squares) were not exposed to −18° C., and stressed vials 6-10 (black triangles) were exposed to −18° C. overnight (17-22 hours). Vials that experienced freeze/thaw had a much lower R₂(¹H₂O) than vials that did not experience freeze/thaw. The average R₂(¹H₂O) for suspended vaccines in vials 1-10 from the 6-day monitoring phase prior to freezing measurements (upper solid lines), with standard deviation of 6 measurements (from 6 different days) was: DAPTACEL 2.541±0.016 s⁻¹, ENGERIX-B 1.239±0.002 s⁻¹, and VAQTA 3.238±0.011 s⁻¹. The average R₂(¹H₂O) for settled vaccines (lower dashed lines) in non-stressed vials 1-5, with standard deviation of 3 measurements (from 3 separate days) was: DAPTACEL 0.653±0.023 s⁻¹, ENGERIX-B 0.687±0.026 s⁻¹, and VAQTA 0.690±0.035 s⁻¹.

FIG. 3E. Noninvasive detection of freeze/thaw of DIPRIVAN (10-ml vial, unopened) vs. invasive detection of freeze/thaw of DIPRIVAN and PROPOFOL (both 20-mL vials, both opened). Noninvasive detection: R₂(¹H₂O) of DIPRIVAN increased from 0.509 to 0.564 s⁻¹ after 1 F/T. Invasive detection: R₂(¹H₂O) of DIPRIVAN increased from 0.549 to 0.612 s⁻¹ after 1 F/T; and R₂(¹H₂O) of PROPOFOL increased from 0.545 to 0.611 s⁻¹ after 1 F/T.

FIG. 3F. Sedimentation kinetics of three aluminum-adjuvanted vaccines, DAPTACEL, ENGERIX-B and VAQTA monitored via R₂(¹H₂O, t). For each product, two vials, one non-stressed (vial #1) and one F/T-stressed (vial #8), were monitored. The F/T-stressed vials of DAPTACEL and ENGERIX-B were frozen and then thawed. The F/T-stressed vial of VAQTA never actually froze. “1-exp” in the figure inset means R₂(¹H₂O) is obtained from fitting the ¹H₂O echo signal intensity data to mono-exponential decay.

FIG. 4A. Comparison of R₂(¹H₂O) values for DAPTACEL (containing ADJU-PHOS (AP) adjuvant, 0.5 mL, vial) vaccine with the 0.5 mL of 0.9% NaCl. Significant difference between the values allows for easy detection of the simple counterfeit.

FIG. 4B. Comparison of R₂(¹H₂O) values for ENGERIX-B (containing ALHYDROGEL (AH) adjuvant, 1.0 mL, vial) vaccine with the 0.5 mL of 0.9% NaCl. Significant difference between the values allows for easy detection of the simple counterfeit.

FIG. 4C. Comparison of R₂(¹H₂O) values for VAQTA (containing AAHS proprietary Merck adjuvant, 1.0 mL, vial) vaccine with the 0.5 mL of 0.9% NaCl. Significant difference between the values allows for easy detection of the simple counterfeit.

FIG. 4D. Comparison of R₂(¹H₂O) values for PREVNAR 13 (containing ADJU-PHOS adjuvant, 0.5 mL, syringe) vaccine with the 0.5 mL of 0.9% NaCl. Significant difference between the values allows for easy detection of the simple counterfeit.

FIG. 4E. Comparison of R₂(¹H₂O) values for BEXSERO (containing ALHYDROGEL adjuvant, 0.5 mL, syringe) vaccine with the 0.5 mL of 0.9% NaCl. Significant difference between the values allows for easy detection of the simple counterfeit.

FIG. 4F. Comparison of R₂(¹H₂O) values for INFANRIX (containing ALHYDROGEL adjuvant, 0.5 mL, syringe) vaccine with the 0.5 mL of 0.9% NaCl. Significant difference between the values allows for easy detection of the simple counterfeit.

FIG. 4G. Comparison of R₂(¹H₂O) values for TDVAX (containing ADJU-PHOS adjuvant, 0.5 mL, vial) vaccine with the 0.5 mL of 0.9% NaCl. Significant difference between the values allows for easy detection of the simple counterfeit.

FIG. 4H. Comparison of R₂(¹H₂O) values for TENIVAC (containing ADJU-PHOS adjuvant, 0.5 mL, vial) vaccine with the 0.5 mL of 0.9% NaCl. Significant difference between the values allows for easy detection of the simple counterfeit.

FIG. 4I. R₂(¹H₂O) vs. τ dependences observed for DAPTACEL and TENIVAC in settled state.

FIG. 4J. R₂(¹H₂O) vs. τ dependences observed for ENGERIX B and PREVNAR 13 in a settled state.

FIG. 4K. R₂(¹H₂O) vs. τ dependences observed for BEXSERO and INFANRIX in a settled state.

FIG. 4L. R₂(¹H₂O) measure of sedimentation kinetics on (initially) fully dispersed suspension vaccines, DAPTACEL and TENIVAC, at a single 0.5 ms τ value.

FIG. 4M. Comparison of sedimentation kinetics of PREVNAR 13 and PREVNAR 20 at two inter-pulse delay τ values collected during a single sedimentation process per product.

FIG. 4N. Comparison of PREVNAR 13 and PREVNAR 20 sedimentation kinetics measured by a ratio of R₂(¹H₂O) at 10 ms τ value to R₂(¹H₂O) at 0.5 ms τ value.

FIG. 4O. R₂(¹H₂O) vs. τ dependences observed for DAPTACEL and TENIVAC. Both vaccines were fully suspended initially (at time=0 min) and the suspension settles over the course of the automated τ-dispersion experiment. The upper abscissa axis shows the sedimentation time while the lower abscissa shows the τ value.

FIG. 4P. R₂(¹H₂O) vs. τ dependences observed for ENGERIX B and PREVNAR 13. Both vaccines were initially in a fully suspended state and naturally sediment over the course of the automated τ-dispersion experiment.

FIG. 4Q. R₂(¹H₂O) vs. τ dependences observed for BEXSERO and INFANRIX. Both vaccines were initially in a fully suspended state and naturally sediment over the course of the automated τ-dispersion experiment.

### DETAILED DESCRIPTION, AND PREFERRED EMBODIMENTS THEREOF

The present invention generally relates to methods for non-invasively identifying substandard or counterfeit products, e.g., vaccines, using nuclear magnetic resonance. The methods described herein provide manufacturers with new approaches to identify parameters to assist with the identification of substandard or counterfeit products.

As defined herein, a “vial” corresponds to a container, vessel, bottle, syringe, injection pen, or ampoule used to store the product, wherein the vial comprises glass, plastic, ceramic, rubber, elastomeric material, and/or any non-magnetic metal. The vial can have a top including, but not limited to, a screw top, a top that is closed using a cork or plastic stopper, a crimp vial (closed with a rubber stopper and a metal cap), a flip-top or snap cap. The vial can be tubular or have a bottle-like shape with a neck. Other types and shapes of vials used to store products as well as caps are readily understood by the person skilled in the art. The vials can be optically transparent or not optically transparent. There is no need to peel off any label on the vial, whether the label is transparent or not.

As defined herein, a “non-destructive” measurement is defined as a measurement performed without opening the vial or otherwise accessing, harming, or altering the product contained in the vial (for example by withdrawing a portion through a rubber gasket). Alternatively, or in addition to not accessing the contents of a vial, a non-destructive measurement means that no additives or probes or the like (e.g., magnetic particles) are added to the vial prior to the measurement of the longitudinal (T₁) or transverse (T₂) relaxation time of solvent or the longitudinal (R₁) or transverse (R₂) relaxation rate of solvent, e.g., water, in the vial. Non-destructive also means that there is no need to make the vials optically transparent and no need to peel off any labels on the vials.

As defined herein, “handling” includes, but is not limited to, manufacturing, fill-finishing, transport, and/or storage of a product.

As defined herein, “substandard” means that the product was not formulated correctly or filled in the vial correctly or has undergone some amount of destruction during handling and should not be used, i.e., administered to a patient. Examples of possible destruction include, but are not limited to: improper formulations, e.g., using the wrong chemical components, incorrect dilutions or contamination; filling errors resulting in a concentration of product that is greater than or less than listed on the vial, e.g., as a result of non-homogeneity or sedimentation; pH changes; unacceptable resuspension; vigorous shaking during transport; accidental heating of the product; accidental freezing of the product; exposure to sunlight; degradation of the product (e.g., aggregation, oxidation or hydrolysis); and repeated freezing and thawing of the product. “Substandard” can also describe a generic of a pioneer or propriety product that is not substantially equivalent to the pioneer or propriety product and should not be used.

As defined herein, a “pharmaceutical product” or “product” can include vaccines and biopharmaceuticals, biologics and small molecules (i.e., non-biologics), in an aqueous medium. The product can further comprise at least one adjuvant, at least one surfactant, at least one water-soluble organic solvent, at least one dispersant, at least one biocide, at least one buffering agent, at least one pH adjusting agent (e.g., acids and/or bases), at least one peptide, at least one polypeptide, at least one protein, at least one antibody or fragment thereof, at least one nucleic acid, at least one oil, or any combination thereof, as readily determined by the person skilled in the art. In some embodiments, the product comprises an emulsion. In some embodiments, the product comprises a vaccine. In some embodiments, the product comprises a solution. In some embodiments, the product comprises a suspension. In some embodiments, the product comprises an emulsion. The product can be transparent or milky or opaque or have color. In some embodiments, the drug product can comprise a protein or a peptide. In some embodiments, the drug product is substantially devoid of any proteins or peptides.

“Substantially devoid” is defined herein to mean that none of the indicated substance is intentionally added to or present in the product. Alternatively, “substantially devoid” can mean that the amount of the indicated substance in the product is less than about 0.1% (w/w), or less than about 0.05% (w/w), or less than about 0.01% (w/w).

It should be appreciated that a “patient” includes any human or other mammal, reptile, bird, fish, or amphibian.

As defined herein, a “biopharmaceutical” includes antibodies, proteins, peptides, nucleic acids, polysaccharides, and combinations thereof. A non-exclusive list of biopharmaceutical products that can be measured for the extent of aggregation includes, but is not limited to, bovine serum albumin; human serum albumin; human γ-globulin; hormones such as insulin, glucagon, gonadotrophins, and growth hormone; haematopoietic growth factors such as erythropoietin; blood factors such as Factor VIII and Factor IX; thrombolytic agents; interferons such as interferon-α, interferon-β, and interferon-γ; interleukin-based products such as interleukin-2; vaccines such as the influenza vaccine; monoclonal antibodies such as adalimumab, rituximab, infliximab, trastuzumab, ustekinumab, denosumab, and golimumab, and including fragments of monoclonal antibodies (e.g., Fc and Fab fragments), variants of monoclonal antibodies, such as single-chain antibodies, bivalent antibodies, and the like, and polyclonal antibody preparations for research or clinical use including therapeutic antibody preparations such as intravenous immunoglobulin (IVIG); tumor necrosis factor; abatacept; alefacept; etanercept; denileukin diftitox; OPTISON; NEUPOGEN; albumin; and ribonuclease A, to name a few.

As defined herein, a “vaccine” can be adjuvanted or not adjuvanted and includes, but is not limited to, an attenuated vaccine comprising an active virus, an inactivated vaccine, toxoid vaccines, a subunit or fragmented vaccine, a conjugate vaccine, an outer membrane vesicle vaccine, a heterologous or heterotypic vaccine, and a genetic vaccine, e.g., mRNA vaccines, viral vector vaccines, DNA vaccines.

As used herein, “counterfeit” products correspond to products sold or provided under a specific brand or generic name that are not manufactured by or on behalf of the owner of said specific brand or generic name. Often the counterfeit compositions are purchased online at a lower cost and are not made according to the exact manufacturing standards of the owner of said specific brand or generic name and/or are less efficacious than the specific brand or generic name product.

As defined herein, a “lot” corresponds to a number of apparently identical vials comprising a product, wherein the vials are provided in the same shipping container or box and/or defined by a manufacturer with a number or code (e.g., a QR code) as being from the same batch of manufactured product. Products in the same lot are assumed to have a uniform character and quality within specified limits. In some embodiments, every vial in a same shipping container or box has the same number or code. In some embodiments, not every vial in a same shipping container or box has the same number or code.

As defined herein, “statistically different” corresponds to a measured value, for example of R₂(¹H₂O) or T₂(¹H₂O), of the alleged counterfeit or substandard product that is (a) greater than 10%, greater than 15%, or greater than 20% of the measured value for the non-substandard product or generic, all other parameters being substantially equal, (b) 6 sigma away from the R₂(¹H₂O) or T₂(¹H₂O) value specified by the manufacturer, wherein 1 sigma is the measurement error, all other parameters being substantially equal, or (c) both (a) and (b).

As used herein, a product “suspected to be substandard or a counterfeit” can correspond to any vial comprising the product in the distribution or supply chain. A product that is “not substandard or a counterfeit” is known and verified by the manufacturer.

It is understood by the person skilled in the art that the “measuring” of the transverse relaxation rate of solvent R₂ or longitudinal relaxation rate of solvent R₁ may be done by measuring some other parameter and converting to the R₂ or R₁ value.

As defined herein, “alum” corresponds to aluminum-containing salts comprising one or more of aluminum hydroxide, aluminum phosphate, alum (KAl(SO₄)·12H₂O), aluminum hydroxyphosphate sulfate, as well as other known or proprietary aluminum salts that can be used as alum adjuvants or in pharmaceutical products comprising aluminum.

As defined herein, the “product comprising aluminum” includes a product with nano- and micron-sized particles comprising aluminum and suspended in a solvent or a mixture of solvents. The alum-containing product can further comprise at least one surfactant, at least one water-soluble organic solvent, at least one dispersant, at least one biocide, at least one buffering agent, at least one pH adjusting agent (e.g., acids and/or bases), with or without antigens, or any combination thereof, as readily determined by the person skilled in the art. Many vaccines are alum-containing products because of the presence of an aluminum adjuvant.

As defined herein, “sophisticated counterfeits” or “sophisticated products” refer to counterfeits that contain one or more components of the real, or non-counterfeit, product. Distinguishing such sophisticated counterfeits from real products is much more challenging than the detection of simple counterfeit products because both comprise similar ingredients.

Recent breakthrough developments in the instrumentation for nuclear magnetic resonance (NMR) spectroscopy and imaging have opened up opportunities to design novel nondestructive analytical techniques for the nanoparticle industry. Of special importance was the introduction of commercially available, relatively inexpensive benchtop and handheld NMR and magnetic resonance imaging (MRI) instruments and relaxometers (Metz, H., et al. 2008. Int. J. Pharm. 364: 170-178). Benchtop NMR instruments enable highly accurate measurements of nuclear spin relaxation times T₁ and T₂. Moreover, most of these instruments have a permanent or electronically cooled magnet with the variable bore from about 10 mm to about 45 mm and even larger which provides a great flexibility in the nonintrusive measurements of vials of various sizes.

Water proton NMR (wNMR) monitors water, which acts as a reporter for analytes dissolved in it. As a reporter, water has many advantages. First, its concentration far surpasses that of any analyte dissolved in it, by 10³-10⁶ fold in most cases. This makes the ¹H₂O signal easily detectable by NMR instruments. Further, the solute association can be detected through the solvent NMR signal. In addition, water is “endogenous” to all biomanufacturing processes and all pharmaceutical products, including vaccines and biotherapeutics. The high concentration of “endogenous” water makes it possible for wNMR to be performed contact-free in situ. Although only examples of products formulated with water as the solvent are presented in this patent application, the extension of NMR to products formulated with other solvents (e.g., ethanol) is contemplated herein.

wNMR is a useful characterization tool for the pharmaceutical industry, thereby allowing the industry to certify products for release, distribution, and clinical use. For example, wNMR can be used to determine if the product has experienced conditions such as heating or freeze/thaw conditions that make it substandard. Further, wNMR can be used to determine if a product is a counterfeit or a substandard generic of a pioneer or propriety product. Law enforcement agencies can use wNMR to check for counterfeit or substandard products. With this information, the manufacturer of the product can determine if the product can be released, the distributor can determine if the product can be distributed, and/or pharmacy or healthcare providers can determine if the product can be administered to patients. In addition, because the measurement of the wNMR can be determined easily using benchtop and handheld NMR devices, the end user (e.g., healthcare professional) can also measure the wNMR of the product to ensure that the product is not substandard or not a counterfeit. This is particularly advantageous since distribution of products subsequent to manufacturing includes the risk of unacceptable temperature fluctuations (e.g., too hot or too cold), unexpected vibrations, and an unknown length of time between bench and bedside.

The methods described herein are reliable and simple methods to assess whether vaccines and other pharmaceutical products are substandard or counterfeits. The methods enable the assessment of the vaccines and other pharmaceutical products, formulated as aqueous suspensions, without the requirement of opening the vial or product container and without peeling off the label on the vial, all while ensuring that the product contained in the vial can still be administered to a patient if it is determined not to be substandard or a counterfeit. The method is quantitative and comprises measuring the nuclear spin relaxation rate constant, R₁ and/or R₂, of solvent, e.g., water, as a quality control parameter.

The instant inventors have previously disclosed methods of determining the quality of products using solvent nuclear magnetic resonance (NMR), for example in U.S. Pat. No. 10,267,754 issued on Apr. 23, 2019, U.S. Pat. No. 10,514,347 issued on Dec. 24, 2019, U.S. Pat. No. 10,724,974 issued on Jul. 28, 2020, U.S. Pat. No. 11,119,061 issued on Sep. 14, 2021, U.S. Pat. No. 11,346,908 issued on May 31, 2022, U.S. patent application Ser. No. 16/593,145 filed on Oct. 4, 2019, U.S. patent application Ser. No. 17/030,088 filed on Sep. 23, 2020, U.S. patent application Ser. No. 17/436,169 filed on Sep. 3, 2021, U.S. patent application Ser. No. 17/206,373 filed on Mar. 19, 2021, U.S. patent application Ser. No. 17/401,709 filed on Aug. 13, 2021, and U.S. patent application Ser. No. 17/842,990 filed on Jun. 17, 2022, all of which are incorporated herein by reference in their entireties. The present application is intended to enhance and expand the applicability of the previously filed patents and patent applications, as well as other applications in the related arts.

Broadly, the methods described herein are intended to identify parameters that enhance the ability to detect substandard and counterfeit products. For example, the inventors' own patents and patent applications related to the use of univariate detection, where, for example, the water proton transverse relaxation rate R₂(¹H₂O) of a product in a vial was non-invasively measured at a fixed inter-pulse delay value (τ) (e.g., at 0.5 ms) and compared to a predetermined standard value or range of R₂(¹H₂O) for that product that is not considered substandard or counterfeit. The use of univariate detection is an incredibly powerful technique, however, there are circumstances where the measured R₂(¹H₂O) of a counterfeit or substandard product at a random τ value is not statistically different than that of a non-counterfeit or acceptable (i.e., not substandard) product. The methods described herein aim to overcome this deficiency.

In a first aspect, a method of using multi-variate NMR to identify a substandard or counterfeit product is described, said method comprising identifying a preferred inter-pulse delay (τ) value for a transverse relaxation rate of solvent R₂ measurement, comprising:
inserting a first vial comprising a product in a nuclear magnetic resonance (NMR) instrument, wherein the product in the first vial is not substandard or a counterfeit;
varying pulse sequence inter-pulse delay (τ) values from x ms to y ms in increments of z ms, wherein z could be any value, but preferably <x and cannot be >y, at a set temperature, and measuring the transverse relaxation rate of solvent R₂ at each τ value, thereby obtaining a fingerprint for the product in the first vial;
inserting a second vial comprising a product suspected to be substandard or counterfeit in the NMR instrument;
varying the same pulse sequence inter-pulse delay (τ) values of x, y, and z, at the same set temperature, and measuring the transverse relaxation rate of solvent R₂ at each τ value, thereby obtaining a fingerprint for the product in the second vial;
identifying the preferred τ value by identifying a τ value where |R₂ (first vial)−R₂ (second vial)| is the greatest between x ms and y ms,
   wherein the transverse relaxation rate of solvent R₂ should be measured at the preferred τ value to identify a vial comprising a substandard or counterfeit of the product in the first vial. Thereafter, additional vials that may be suspected of being a substandard or counterfeit of the product in the first vial can be measured at the preferred τ value to determine if they are substandard or counterfeit.

In some embodiments of the first aspect, a method of using multi-variate NMR to identify a substandard or counterfeit product is described, said method comprising:
identifying a preferred inter-pulse delay (τ) value for a transverse relaxation rate of water R₂(¹H₂O) measurement by:
   inserting a first vial comprising a product in a nuclear magnetic resonance (NMR) instrument, wherein the product in the first vial is not substandard or a counterfeit;
   varying pulse sequence inter-pulse delay (τ) values from x ms to y ms in increments of z ms, wherein z could be any value, but preferably <x and cannot be >y, at a set temperature, and measuring the R₂(¹H₂O) at each τ value, thereby obtaining a first fingerprint for the product in the first vial;
   inserting a second vial comprising a product suspected to be substandard or counterfeit in the NMR instrument;
   varying the same pulse sequence inter-pulse delay (τ) values of x, y, and z, at the same set temperature, and measuring the R₂(¹H₂O) at each τ value, thereby obtaining a second fingerprint for the product in the second vial;
   identifying the preferred τ value by identifying a τ value where |R₂(¹H₂O) (first vial)−R₂(¹H₂O) (second vial)| is the greatest between x ms and y ms,
wherein the transverse relaxation rate of solvent R₂ should be measured at the preferred τ value to identify a vial comprising a substandard or counterfeit of the product in the first vial. It should be appreciated by the person skilled in the art that the “n^{th} vial” is intended to signify any vial that is measured that is not the first or second vial.

In some embodiments, the value of x, y, and z are determined by the user measuring the transverse relaxation rate of solvent R₂ of the product in the first vial. In some embodiments, the value of x is 1 or less, e.g., 0.1, 0.2, 0.3, 0.4, 0.5, 0.6, 0.7, 0.8, 0.9, the value of y is 10 or more, e.g., 10, 15, 20, 25, and the value of z can be any value less than x, for example, 0.05, 0.1, 0.15, 0.2, 0.25, 0.3, etc. In some embodiments, y/z is 20 or greater. In some embodiments, y/z is 30 or greater. In some embodiments, y/z is 40 or greater. The greater the value of y/z (which is the number of varied τ values that the transverse relaxation rate of solvent R₂ is being measured at), the more complete fingerprint of the product can be obtained. In some embodiments, the value of x is 0.5, the value of y is 10, and the value of z is 0.25, for a total of 40 τ values, or transverse relaxation rate of solvent R₂ measurements.

In some embodiments, the product in the first vial is verified by the manufacturer prior to vial filling and prior to obtaining the preferred τ value, using other methods known in the pharmaceutical arts. In some embodiments, the method of the first aspect is carried out non-invasively, wherein the first and second vials are inserted into the core of the NMR without opening the vials or peeling off the label. In some embodiments, instead of the transverse relaxation rate of solvent R₂, the longitudinal relaxation rate of solvent R₁ is used instead. The method of the first aspect is agnostic to the actual first and second vials. In other words, the vials can have different shapes and sized and/or be made of different materials, as long as they are not paramagnetic or ferromagnetic, and the specific fingerprint will be substantially identical.

Advantageously, the method of the first aspect provides an optimized parameter that permits transporters, law enforcement and medical professionals to more definitively identify counterfeits or substandard products, where previously it was difficult to do so because of the statistically similar transverse relaxation rate of solvent R₂ values at a set, and not optimized, τ value. The method of the first aspect is particularly useful for the manufacturer that is familiar with the expected counterfeit or substandard product that the transporters, law enforcement and medical professionals may encounter once the product leaves the manufacturer. For example, a common counterfeit of many products is just water or a saline solution. The manufacturer can identify the preferred τ value, and optionally the fingerprint of the product of the first vial, using the method of the first aspect and provide same in the package insert, on the vial label, on the website, or any of the above. Thereafter, the transporter, law enforcement or medical professional, who may not have a sample of the non-counterfeit or acceptable (i.e., not substandard) product, can measure the transverse relaxation rate of solvent R₂ of the vials in a lot at the preferred τ value and more easily identify if they have in their possession a substandard or counterfeit product. A rejected vial should be removed from the distribution chain and not used. Alternatively, the method of the first aspect provides professionals such as manufacturers, transporters, law enforcement and medical professionals to more definitively identify counterfeits or substandard products when they have access to the non-counterfeit or acceptable (i.e., not substandard) product (i.e., the first vial) and they want to determine if a lot of product (i.e., containing a second vial and additional n^{th} vials) is counterfeit or substandard. The first and second fingerprints and the preferred τ value can be obtained, using the method of the first aspect, and thereafter, the transverse relaxation rate of solvent R₂ of the vials in the lot at the preferred τ value can be measured to identify if they have in their possession a substandard or counterfeit product. A rejected vial should be removed from the distribution chain and not used.

In a second aspect, a method of using multi-variate NMR to identify a substandard or counterfeit product in a lot is described, said method comprising:
inserting a vial comprising a second product in a nuclear magnetic resonance (NMR) instrument, wherein the second product is suspected to be substandard or a counterfeit of a first product;
varying pulse sequence inter-pulse delay (τ) values from x ms to y ms in increments of z ms, wherein z could be any value, but preferably <x and cannot be >y, at a set temperature, wherein the values of x, y, and z are specific to the first product and intended for the identification of a substandard or counterfeit product, and measuring the transverse relaxation rate of solvent R₂ at each τ value, thereby obtaining a fingerprint for the second product in the vial;
comparing a fingerprint provided for the first product with the fingerprint obtained for the second product;
identifying the preferred τ value by identifying a τ value where |R₂ (first product)−R₂ (second second)| is the greatest between x ms and y ms; and
using the preferred τ value when measuring the transverse relaxation rate of solvent R₂ of other vials in the lot,
   wherein a substandard or counterfeit product in the lot is identified when the transverse relaxation rate of solvent R₂ is statistically different than the transverse relaxation rate of solvent R₂ of the first product at the preferred τ value. Thereafter, additional vials that may be suspected of being a substandard or counterfeit of the product in the first vial can be measured at the preferred τ value to determine if they are substandard or counterfeit.

In some embodiments of the second aspect, a method of using multi-variate NMR to identify a substandard or counterfeit product in a lot is described, said method comprising:
inserting a vial comprising a second product in a nuclear magnetic resonance (NMR) instrument, wherein the second product is suspected to be substandard or a counterfeit of a first product;
varying pulse sequence inter-pulse delay (τ) values from x ms to y ms in increments of z ms, wherein z could be any value, but preferably <x and cannot be >y, at a set temperature, and measuring the transverse relaxation rate of solvent R₂ at each τ value, thereby obtaining a second fingerprint for the second product in the vial, wherein the values of x, y, and z are specific to the first product and intended for the identification of a substandard or counterfeit product;
comparing a first fingerprint provided for the first product with the second fingerprint obtained for the second product;
identifying the preferred τ value by identifying a τ value where |R₂(¹H₂O) (first product)−R₂(¹H₂O) (second second)| is the greatest between x ms and y ms; and
using the preferred τ value when measuring the R₂(¹H₂O) of other vials in the lot,
   wherein a substandard or counterfeit product in the lot is identified when the R₂(¹H₂O) is statistically different than the R₂(¹H₂O) of the first product at the preferred τ value. Thereafter, additional vials that may be suspected of being a substandard or counterfeit of the product in the first vial can be measured at the preferred τ value to determine if substandard or counterfeit.

In some embodiments, the value of x, y, and z are provided to the user measuring the transverse relaxation rate of solvent R₂ of the product in the second vial. In some embodiments, the x, y, and z values are provided on a provided set of instructions or on a website. In some embodiments, the value of x is 1 or less, e.g., 0.1, 0.2, 0.3, 0.4, 0.5, 0.6, 0.7, 0.8, 0.9, the value of y is 10 or more, e.g., 10, 15, 20, 25, and the value of z can be any value less than x, for example, 0.05, 0.1, 0.15, 0.2, 0.25, 0.3, etc. In some embodiments, y/z is 20 or greater. In some embodiments, y/z is 30 or greater. In some embodiments, y/z is 40 or greater. The greater the value of y/z (which is the number of varied τ values that the transverse relaxation rate of solvent R₂ is being measured at), the more complete fingerprint of the product can be obtained. In some embodiments, the value of x is 0.5, the value of y is 10, and the value of z is 0.25, for a total of 40 τ values, or transverse relaxation rate of solvent R₂ measurements.

In some embodiments, the product in the first vial is verified by the manufacturer prior to vial filling and prior to obtaining the preferred τ value, using other methods known in the pharmaceutical arts. In some embodiments, the method of the second aspect is carried out non-invasively, wherein the second vial is inserted into the core of the NMR without opening the vial or peeling off the label. In some embodiments, instead of the transverse relaxation rate of solvent R₂, the longitudinal relaxation rate of solvent R₁ is used instead. The method of the second aspect is agnostic to the actual first and second vials. In other words, the vials can have different shapes and sized and/or be made of different materials, as long as they are not paramagnetic or ferromagnetic, and the fingerprint will be substantially identical.

In the second aspect, the first product is not substandard or a counterfeit. In some embodiments, the user does not have a vial comprising the first product available, just the relevant parameters, data and figures provided by the manufacturer. Advantageously, the method of the second aspect permits transporters, law enforcement and medical professionals to identify substandard or counterfeit products when details about the product in a lot are previously unknown. For example, a lot or container of vials comprising an alleged product (i.e., the second product) can be obtained by law enforcement. They can determine if some, or all, of the vials in the lot are substandard or counterfeit by obtaining a second fingerprint of the second product and comparing it to the provided fingerprint of the first product (e.g., as provided by the manufacturer). A preferred τ value can be obtained and thereafter the user can check all of the other vials of the second product in the lot. A substandard or counterfeit product in the lot is identified when the transverse relaxation rate of solvent R₂ is statistically different than the transverse relaxation rate of solvent R₂ of the first product at the preferred τ value, which can be obtained from the fingerprint of the first product. A rejected vial should be removed from the distribution chain and not used.

In some embodiments, the method of the first and second aspect are applicable to products comprising solutions, emulsions, and settled suspensions (i.e., dosage forms that do not settle).

In a third aspect, a method of using a sedimentation rate to identify a substandard or counterfeit product is described, said method comprising:
measuring a sedimentation rate of a product contained in a first vial using a nuclear magnetic resonance (NMR) instrument, wherein the product in the first vial is not substandard or a counterfeit;
measuring a sedimentation rate of a product contained in a second vial using the NMR instrument, wherein the product in the second vial is suspected to be substandard or counterfeit; and
comparing the sedimentation rate of the product in the first vial and the product in the second vial,
   wherein a substandard or counterfeit product is identified when the sedimentation rate of the product in the second vial is statistically different than the sedimentation rate of the product in the first vial.

In some embodiments, the product of the first vial and the second vial is a dispersed suspension. In some embodiments, the product of the first vial and the second vial comprises an aluminum adjuvant. In some embodiments, the aluminum adjuvant comprises alum particles. In some embodiments, the method of the third aspect further comprises: fully dispersing the product contained in the first vial, wherein the product is a suspension; immediately inserting the first vial in a nuclear magnetic resonance (NMR) instrument; measuring a transverse relaxation rate of solvent R₂ at a single τ value over time t; and determining the sedimentation rate of the product in the first vial using a sedimentation kinetics profile (R₂(solvent, t)) of the product. In some embodiments, the method of the third aspect further comprises: fully dispersing the product contained in the first vial, wherein the product is a suspension; immediately inserting the first vial in a nuclear magnetic resonance (NMR) instrument; measuring a transverse relaxation rate of water R₂(¹H₂O) at a single τ value over time t; and determining the sedimentation rate of the product in the first vial using a sedimentation kinetics profile (R₂(¹H₂O, t)) of the product. In some embodiments, the method of the third aspect further comprises: fully dispersing the product contained in the second vial, wherein the product is a suspension; immediately inserting the second vial in a nuclear magnetic resonance (NMR) instrument; measuring a transverse relaxation rate of solvent R₂ at a single τ value over time t; and determining the sedimentation rate of the product in the second vial using a sedimentation kinetics profile (R₂(solvent, t)) of the product. In some embodiments, the method of the third aspect further comprises: fully dispersing the product contained in the second vial, wherein the product is a suspension; immediately inserting the second vial in a nuclear magnetic resonance (NMR) instrument; measuring a transverse relaxation rate of water R₂(¹H₂O) at a single τ value over time t; and determining the sedimentation rate of the product in the second vial using a sedimentation kinetics profile (R₂(¹H₂O, t)) of the product.

In some embodiments, the method of the third aspect is carried out non-invasively, wherein the first and second vials are inserted into the core of the NMR without opening the vials or peeling off the label. In some embodiments, instead of the transverse relaxation rate of solvent R₂, the longitudinal relaxation rate of solvent R₁ is used instead. The method of the third aspect is agnostic to the actual first and second vials. In other words, the vials can have different shapes and sizes and/or be made of different materials, as long as they are not paramagnetic or ferromagnetic, and the sedimentation rates can still be compared.

In a fourth aspect, a fingerprint of a product contained in a vial is obtained, said method comprising measuring transverse relaxation rate of solvent R₂ over time at two alternating τ-values of a fully dispersed product in said vial, wherein the product is a suspension, and wherein the transverse relaxation rate of solvent R₂ at multiple, alternating τ-values is collected throughout a sedimentation process of the product. In some embodiments, the two alternating τ-values can be x ms and y ms, wherein the value of x is 1 or less, e.g., 0.1, 0.2, 0.3, 0.4, 0.5, 0.6, 0.7, 0.8, 0.9, and the value of y is 10 or more, e.g., 10, 15, 20, 25. The data R₂(¹H₂O, t, τ), forms a fingerprint for a sophisticated product. In some embodiments, the transverse relaxation rate of water Rₛ(¹H₂O) is measured instead.

In some embodiments, the method of the fourth aspect is used to identify a substandard or counterfeit product, said method comprising:
inserting a first vial comprising a product in a nuclear magnetic resonance (NMR) instrument, wherein the product in the first vial is not substandard or a counterfeit;
measuring transverse relaxation rate of solvent R₂ over time at two alternating τ-values of a fully dispersed product in said first vial, wherein the product is a suspension, and wherein the transverse relaxation rate of solvent R₂ at the alternating τ-values is collected throughout a sedimentation process of the product in the first vial;
inserting a second vial comprising a product in the NMR instrument, wherein the product in the second vial is suspected to be substandard or a counterfeit of the product in the first vial;
measuring transverse relaxation rate of solvent R₂ over time at two alternating τ-values of a fully dispersed product in said second vial, wherein the product is a suspension, and wherein the transverse relaxation rate of solvent R₂ at the alternating τ-values is collected throughout a sedimentation process of the product in the second vial; and
identifying a preferred τ-value by selecting one of the two alternating τ-values where the transverse relaxation rate of solvent R₂ is statistically different;
   wherein a substandard or counterfeit product is identified by measuring the transverse relaxation rate of solvent R₂ of a fully dispersed product in a n^{th} vial, at the preferred τ value, wherein the sedimentation rate of the product in the n^{th} vial is substantially different than the sedimentation rate of the product in the first vial.

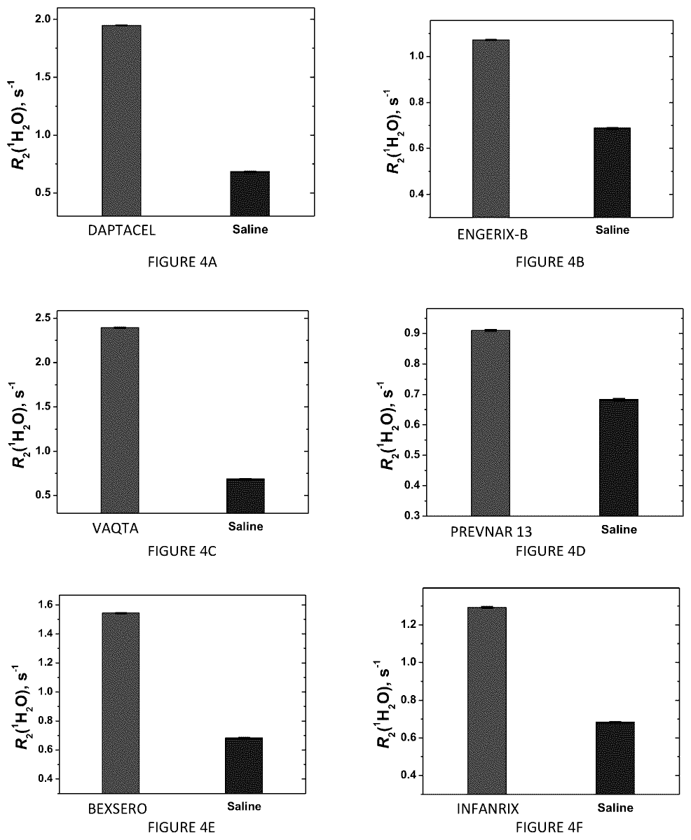

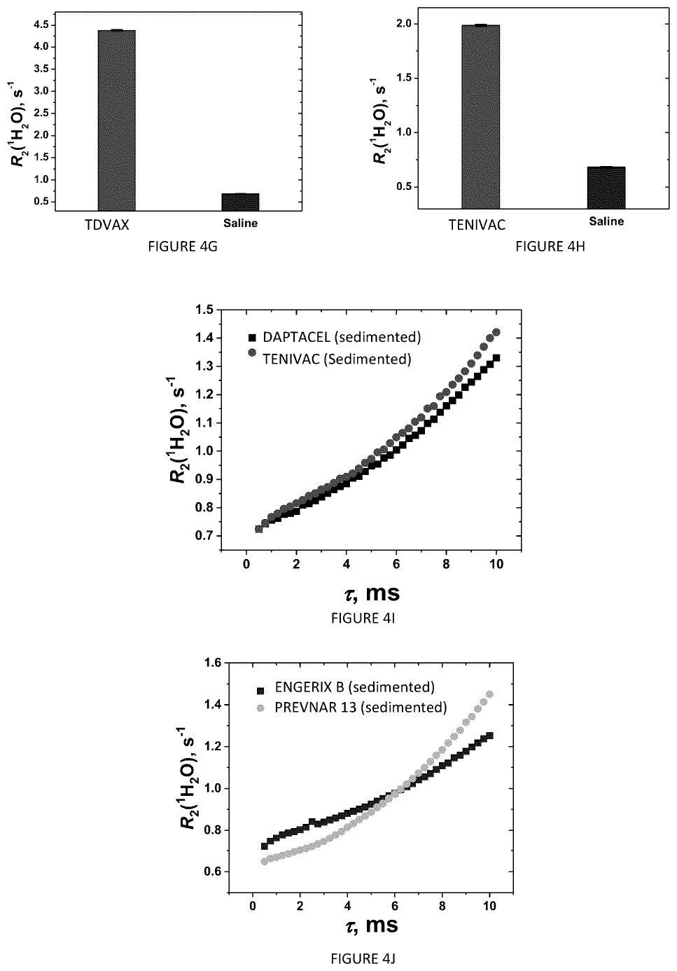

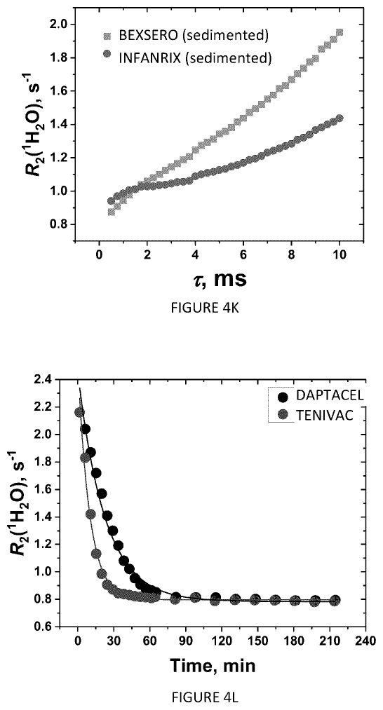

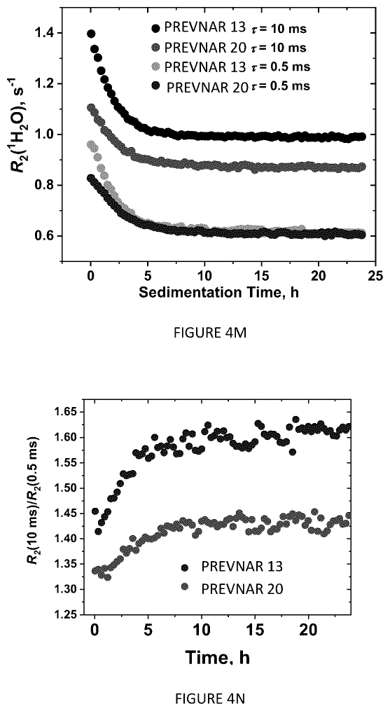

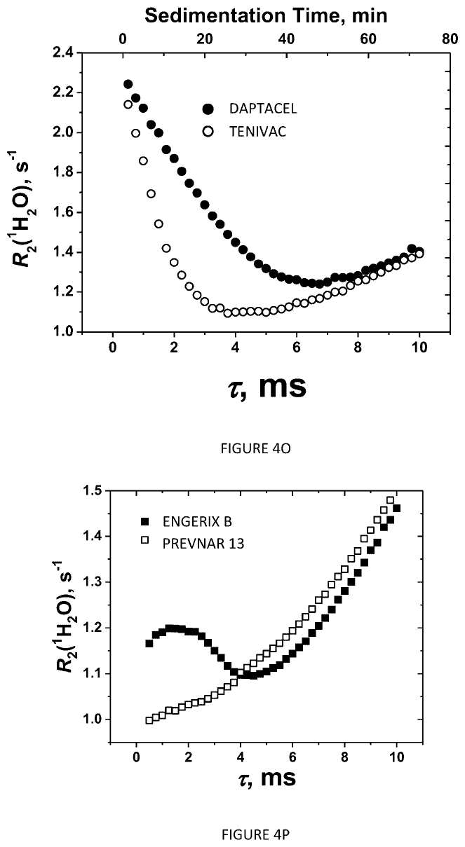

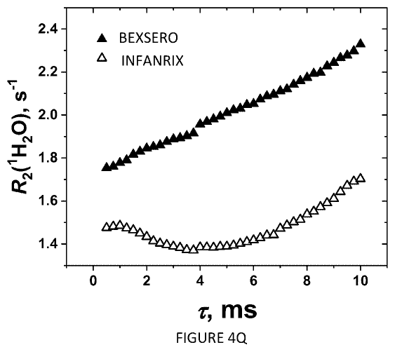

In some embodiments, the method of the fourth aspect permits the selection of a preferred τ-value for subsequent sedimentation methods, e.g., the method of the third aspect. An example of this is shown in FIG. 4M discussed herein.

In some embodiments, the method of the fourth aspect is carried out non-invasively, wherein the first and second vials are inserted into the core of the NMR without opening the vials or peeling off the label. In some embodiments, instead of the transverse relaxation rate of solvent R₂, the longitudinal relaxation rate of solvent R₁ is used instead. The method of the fourth aspect is agnostic to the actual first and second vials. In other words, the vials can have different shapes and sizes and/or be made of different materials, as long as they are not paramagnetic or ferromagnetic, and the R₂(¹H₂O, t, τ) can still be obtained and compared. In some embodiments, the two alternating τ-values can be x ms and y ms, wherein the value of x is 1 or less, e.g., 0.1, 0.2, 0.3, 0.4, 0.5, 0.6, 0.7, 0.8, 0.9, and the value of y is 10 or more, e.g., 10, 15, 20, 25. The data R₂(¹H₂O, t, τ), forms a fingerprint for sophisticated a product. In some embodiments, the transverse relaxation rate of water R₂(¹H₂O) is measured. Advantageously, the method of the fourth aspect involving multi-variate NMR can produce fingerprints of a product for product authentication and counterfeit detection.

In some embodiments, the method of the fourth aspect further comprises: fully dispersing the product contained in a vial, wherein the product is a suspension; immediately inserting a vial in a nuclear magnetic resonance (NMR) instrument; and measuring a transverse relaxation rate of solvent R₂ at the two alternating τ values. In some embodiments, the method of the fourth aspect further comprises: fully dispersing the product contained in a vial, wherein the product is a suspension; immediately inserting the vial in a nuclear magnetic resonance (NMR) instrument; and measuring a transverse relaxation rate of water R₂(¹H₂O) at the two alternating τ values.

In some embodiments, the method of the fourth aspect further comprises determining the ratio of R₂(y ms)/R₂(x ms), as a function of time, for a first vial and comparing it to the same ratio, as a function of time, for a second vial. The results provide another way to distinguish sophisticated products from one another, e.g., as shown in FIG. 4N.

In a fifth aspect, multi-variate NMR is used to capture the dependence of the transverse relaxation rate of solvent R₂(solvent, t), but also the dependence of the transverse relaxation rate of solvent R₂(solvent, τ), synergistically providing a complex fingerprint of an individual product, wherein the product comprises a dispersed suspension, e.g., a vaccine formulation.

In some embodiments, the method of the fifth aspect is used to identify a substandard or counterfeit product, said method comprising:
inserting a first vial comprising a product in a nuclear magnetic resonance (NMR) instrument, wherein the product in the first vial is not substandard or a counterfeit;
measuring transverse relaxation rate of solvent R₂ over time at multiple τ-values of a fully dispersed product in said first vial, wherein the product is a suspension, and wherein the transverse relaxation rate of solvent R₂ at multiple τ-values is collected throughout a sedimentation process of the product in the first vial;
inserting a second vial comprising a product in the NMR instrument, wherein the product in the second vial is suspected to be substandard or a counterfeit of the product in the first vial;
measuring transverse relaxation rate of solvent R₂ over time at multiple τ-values of a fully dispersed product in said second vial, wherein the product is a suspension, and wherein the transverse relaxation rate of solvent R₂ at multiple τ-values is collected throughout a sedimentation process of the product in the second vial; and
plotting the transverse relaxation rate of solvent R₂ as a function of τ for both the first and second vial to obtain a first fingerprint corresponding to the first vial and a second fingerprint corresponding to the second vial, respectively,
   wherein if the first fingerprint and the second fingerprint are not substantially identical, the product in the second vial is a substandard or counterfeit of the product in the first vial. Thereafter, additional vials that may be suspected of being a substandard or counterfeit of the product in the first vial can be measured and plotted and compared to the first fingerprint to determine if substandard or counterfeit.

In some embodiments, the multiple τ-values are obtained by varying pulse sequence inter-pulse delay (τ) values from x ms to y ms in increments of z ms, wherein z could be any value, but preferably <x and cannot be >y, at a set temperature. In some embodiments, the value of x, y, and z are provided to the user measuring the transverse relaxation rate of solvent R₂ of the product in the second vial. In some embodiments, the x, y, and z values are provided on a provided set of instructions or on a website. In some embodiments, the value of x is 1 or less, e.g., 0.1, 0.2, 0.3, 0.4, 0.5, 0.6, 0.7, 0.8, 0.9, the value of y is 10 or more, e.g., 10, 15, 20, 25, and the value of z can be any value less than x, for example, 0.05, 0.1, 0.15, 0.2, 0.25, 0.3, etc. In some embodiments, y/z is 20 or greater. In some embodiments, y/z is 30 or greater. In some embodiments, y/z is 40 or greater. The greater the value of y/z (which is the number of varied τ values that the transverse relaxation rate of solvent R₂ is being measured at), the more complete fingerprint of the product can be obtained. In some embodiments, the value of x is 0.5, the value of y is 10, and the value of z is 0.25, for a total of 40 τ values, or transverse relaxation rate of solvent R₂ measurements.

In some embodiments, the method of the fifth aspect is carried out non-invasively, wherein the first and second vials are inserted into the core of the NMR without opening the vials or peeling off the label. In some embodiments, instead of the transverse relaxation rate of solvent R₂, the longitudinal relaxation rate of solvent R₁ is used instead. The method of the fifth aspect is agnostic to the actual first and second vials. In other words, the vials can have different shapes and sizes and/or be made of different materials, as long as they are not paramagnetic or ferromagnetic, and the R₂ versus τ can still be obtained and compared. In some embodiments, the transverse relaxation rate of water R₂(¹H₂O) is measured.

In some embodiments, the method of the fifth aspect further comprises: fully dispersing the product contained in a vial, wherein the product is a suspension; immediately inserting a vial in a nuclear magnetic resonance (NMR) instrument; and measuring a transverse relaxation rate of solvent R₂ at multiple τ values. In some embodiments, the method of the fifth aspect further comprises: fully dispersing the product contained in a vial, wherein the product is a suspension; immediately inserting the vial in a nuclear magnetic resonance (NMR) instrument; and measuring a transverse relaxation rate of water R₂(¹H₂O) at multiple τ values.

The methods described herein are a reliable and simple method to assess whether a product contained in a vial is substandard or is a counterfeit or substandard generic of a pioneer or propriety product. The methods described herein are qualitative and/or quantitative and comprise determining the nuclear spin relaxation rate constant of solvent, e.g., R₁(¹H₂O) and/or R₂(¹H₂O), as a quality control parameter.

In addition to being noninvasive, additional advantages of low field solvent NMR includes, but is not limited to, low cost instrumentation (e.g., a desktop or handheld NMR), simple and rapid data acquisition and analysis, and minimal technical expertise requirement. It should be appreciated that the measurements can occur destructively as well, whereby the vial is opened, if needed. Further, the method described herein can utilize high field NMR, if needed.

The present subject matter may be a system, a method, and/or a computer program product. In some embodiments, the computer program product may include a computer readable storage medium (or media) having computer readable program instructions thereon for causing a processor to carry out aspects of the present subject matter.

In some embodiments, the computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a RAM, a ROM, an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

In some embodiments, computer readable program instructions described herein can be downloaded to respective computing/processing devices from a computer readable storage medium or to an external computer or external storage device via a network, for example, the Internet, a local area network, a wide area network and/or a wireless network, or Near Field Communication. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

In some embodiments, computer readable program instructions for carrying out operations of the present subject matter may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Smalltalk, C++, Javascript or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present subject matter.

In some embodiments, the computer readable program instructions may be provided to a processor of a computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. In some embodiments, the computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

In some embodiments, the computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The features and advantages of the invention are more fully shown by the illustrative examples discussed below.

### Example 1

### Example for Emulsion Counterfeit Detection

Two small molecule drugs formulations as oil-in-water emulsions were used to illustrate the detection of counterfeit pharmaceutical products formulated as aqueous solutions using wNMR. The two emulsions drugs were DIPRIVAN and PROPOFOL; DIPRIVAN is the innovator drug and PROPOFOL is its FDA-approved generic. The active pharmaceutical ingredient (API) in both drugs is 2,6-diisopropylphenol.

For the sake of this experiment, DIPRIVAN and PROPOFOL will serve as each other's complex counterfeit. For emulsions, simple counterfeits like water or physiological saline, can be visually distinguished from an actual emulsion drug product. Accordingly, in the present experiment, a lipid emulsion product, INTRALIPID, a nutritional supplement for intravenous delivery, was used to serve as a simple counterfeit of DIPRIVAN, since they are visually similar in their white opacity.

a. Using Univariate wNMR to Detect Simple Counterfeit Emulsion Products

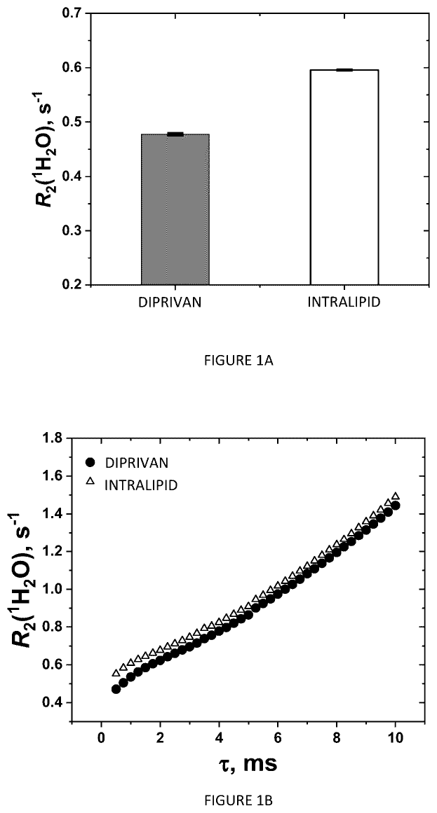

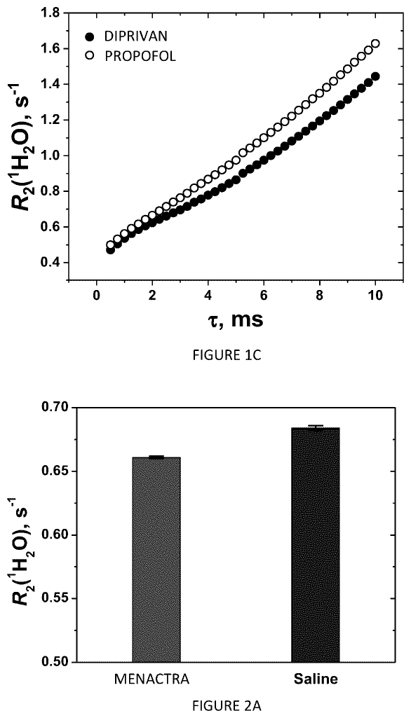

FIG. 1 shows a comparison of the water proton transverse relaxation rate, R₂(¹H₂O), of a real emulsion product in its original vial, DIPRIVAN, with a simple counterfeit INTRALIPID, 20%. All measurements were done noninvasively using the Carr-Purcell-Meiboom-Gill (CPMG) pulse sequence, at the same inter-pulse delay time τ (0.5 ms), at 25° C., in the probe cavity of variable temperature benchtop NMR spectrometer (VT-NMR). All measurements were done in triplicate, and the error bars show the standard deviations of three consecutive measurements.

Water proton transverse relaxation time T₂(¹H₂O) measured using CPMG pulse sequence was extracted by fitting experimental echo decay data to Formula (1):

I(t)=I₀×exp(−t/T₂(¹H₂O)) (1)

where I(t) is the water proton echo signal intensity at time t, I₀ is the initial water proton echo signal at t=0, and t is the echo delay time. Extracted water proton relaxation time T₂(¹H₂O) values were converted to water proton relaxation rate R₂(¹H₂O) using Formula (2):

R₂(¹H₂O)=1/T₂(¹H₂O) (2)

The person skilled in the art would understand that other methods and NMR instruments can be used to determine T₂(¹H₂O), and the CPMG pulse sequence used herein is not intended to limit the determination of T₂(¹H₂O), and ultimately R₂(¹H₂O).
b. Using Type I Multi-Variate wNMR to Detect Simple Counterfeit Emulsion Products

In Type I multi-variate wNMR, R₂(¹H₂O) is measured at multiple τ-values, where the inter-pulse delay, τ, is an adjustable parameter in the CPMG pulse sequence used to measure R₂(¹H₂O). In Type I measurements, R₂(¹H₂O, τ) is performed on emulsions noninvasively, in the original vial. In this multi-variate wNMR experiment, the CPMG pulse sequence inter-pulse delay, τ, was varied from 0.5 ms to 10 ms by increments of 0.25 ms (˜40 different τ-values per emulsion) at a set sample temperature of 25° C. in the probe cavity of a VT-NMR. FIG. 1B compares the R₂(¹H₂O, τ) profiles of INTRALIPID and DIPRIVAN. The two profiles indicate that for this pair, a larger R₂(¹H₂O) difference is achieved in the low τ region, e.g., about τ=0.5 ms.

c. Using Univariate wNMR to Detect Sophisticated Counterfeit Vaccines

Table 1 lists a single R₂(¹H₂O) for two 2,6-diisopropylphenol emulsion products, brand name, DIPRIVAN, and generic, PROPOFOL, which for the purpose of this study, we considered the sophisticated complex counterfeit. All measurements were done noninvasively using the CPMG pulse sequence, at the same inter-pulse delay time τ (0.5 ms), at 25° C., in the probe cavity of VT-NMR. It can be seen that for these two emulsions, the R₂(¹H₂O) values differ by more than the measurement error, which means a single R₂(¹H₂O) may be used to distinguish between them.

TABLE 1
The R₂(¹H₂O) at τ = 0.5 ms for emulsion product
DIPRIVAN and its complex counterfeit PROPOFOL.

| Emulsion Product | R₂(¹H₂O), s⁻¹ |
|---|---|
| Diprivan ® (Brand) | 0.477 ± 0.002 |
| Propofol ® (Generic) | 0.503 ± 0.001 |

d. Using Type I Multi-Variate wNMR to Detect Sophisticated Counterfeit Vaccines

In Type I multi-variate wNMR, R₂(¹H₂O) is measured at multiple τ-values, where the inter-pulse delay, τ, is an adjustable parameter in the CPMG pulse sequence used to measure R₂(¹H₂O). In Type I measurements, R₂(¹H₂O, τ) is performed on emulsions noninvasively, in the original vial. Two marketed emulsion products with close values of water proton transverse relaxation rates, R₂(¹H₂O), at a single τ-value (0.5 ms) were selected for the experiment. In this multi-variate wNMR experiment, the CPMG pulse sequence inter-pulse delay, τ, was varied from 0.5 ms to 10 ms by increments of 0.25 ms (˜40 different τ-values per emulsion) at a set sample temperature of 25° C. in the probe cavity of a VT-NMR.

FIG. 1C shows a comparison of the dependence of water proton transverse relaxation rates R₂(¹H₂O) vs. τ for the two emulsion products, DIPRIVAN and PROPOFOL. Note that both emulsions are presented in glass vials containing 20 mL of the emulsion, and both have the same concentrations of the API 2,6-diisopropylphenol. In FIG. 1C, a larger difference in R₂(¹H₂O) between these two emulsion products is achieved in the high τ region than in the low τ region. This result demonstrates that Type I multi-variate wNMR may help to optimize univariate wNMR such that the optimized univariate wNMR can differentiate the real product from the counterfeit, such as a single R₂(¹H₂O) measured at an optimized τ (e.g., 10 ms instead of 0.5 ms as in the current example).

These results clearly demonstrate the fingerprinting potential of τ-dispersion profiles and confirm the capability of wNMR technology to differentiate between real and counterfeit emulsion products, including sophisticated counterfeits. Further, in actual practice, multi-variate wNMR may be used to optimize univariate wNMR for counterfeit detection (e.g., through optimizing the inter-pulse separation τ in the CPMG pulse sequence).

e. Other Types of Multi-Variate wNMR

With emulsion products, in addition to single exponential fitting, double exponential fitting of the data reveals more information about the oil and water components of the emulsion. In certain cases of counterfeits, double exponential fitting can provide another layer of information about a product. In addition, R₁(¹H₂O) analysis may also be used instead of R₂(¹H₂O) analysis.

### Example 2

### Examples for Solution Counterfeit Detection

In this example, non-adjuvanted vaccines and biotherapeutics are used to illustrate wNMR capability to detect counterfeit pharmaceutical products formulated as aqueous solutions.

a. Detecting Simple Counterfeit Vaccine Products Using Univariate wNMR

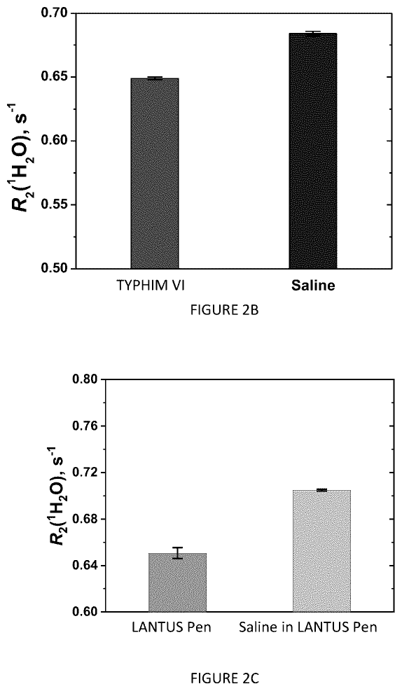

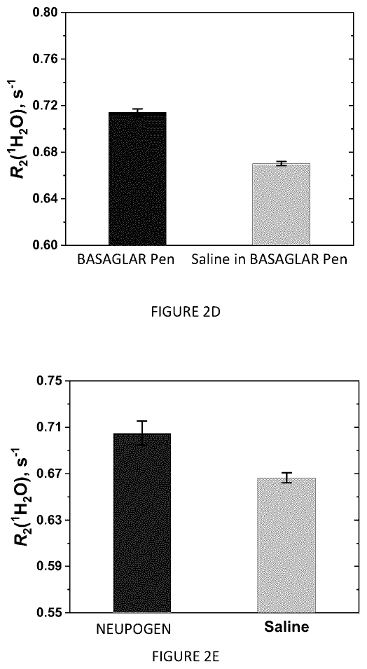

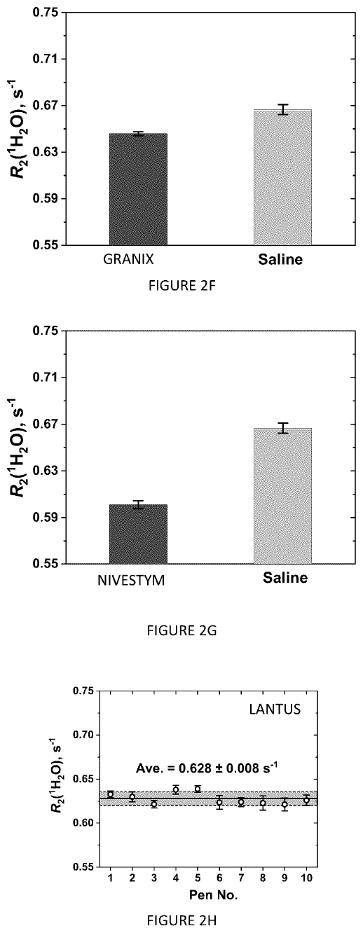

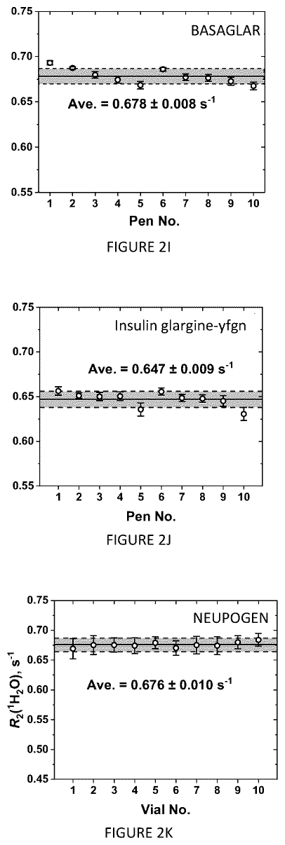

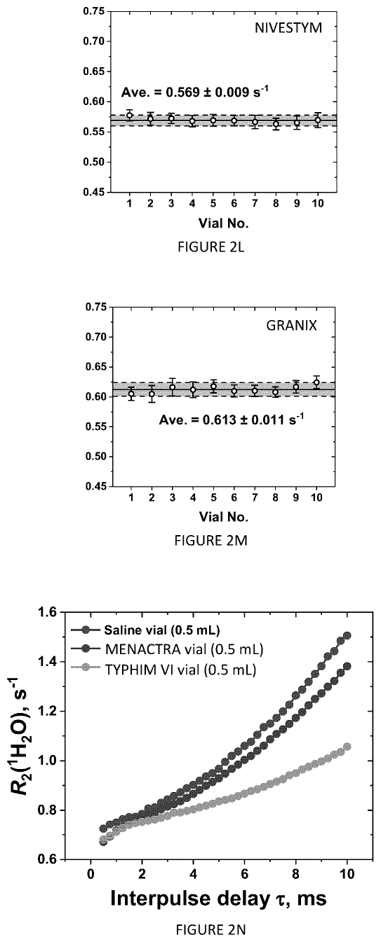

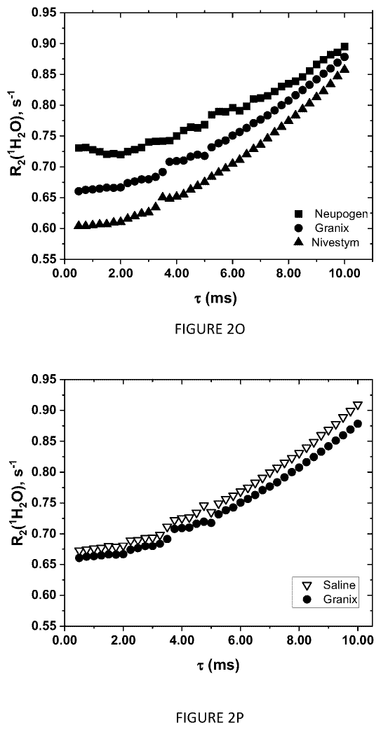

Physiological saline serves as a simple counterfeit to vaccines formulated as solutions. FIGS. 2A and 2B show the comparisons of real vaccine products in their original vials or pre-filled syringes with a simple counterfeit (sterile 0.9% NaCl saline) in a sealed vial, as measured by water proton transverse relaxation rates, R₂(¹H₂O). All measurements were done noninvasively using the CPMG pulse sequence, at the same inter-pulse delay time τ (0.5 ms), at 5° C., in the probe cavity of VT-NMR. All measurements were done in triplicate, and the error bars show the standard deviations of three consecutive measurements. In both FIGS. 2A and 2B, the difference between the R₂(¹H₂O) values are statistically significant, which means a single R₂(¹H₂O) may be used to distinguish between them.

In summary, a single R₂(¹H₂O) (univariate wNMR) can readily distinguish vaccine products formulated as aqueous solutions from a simple counterfeit such as physiological saline.

b. Detecting Simple Counterfeit Biotherapeutic Products Using Univariate wNMR

Physiological saline serves as a simple counterfeit to biotherapeutics formulated as solutions. For comparison of real biotherapeutics with the simple counterfeits, the water proton relaxation rate R₂(¹H₂O) of two insulin glargine drug products in pre-filled pens, LANTUS and BASAGLAR, and three filgrastim drug products in sealed vials, NEUPOGEN, GRANIX, and NIVESTYM, were measured. For each of the above products, simple counterfeits were created by placing the corresponding amount of the sterile saline (0.9% NaCl) solution in the respective drug container. Specifically, one LANTUS pen and one BASAGLAR pen were emptied and refilled with 3 mL of saline. A sealed glass vial filled with 1 mL of saline, which was similar to the ones used for NEUPOGEN, GRANIX, and NIVESTYM, served as a simple counterfeit for these drug products. All measurements were done noninvasively using the CPMG pulse sequence, at the same interpulse delay time τ (0.5 ms), at 5° C., in the probe cavity of VT-NMR. All measurements were done in triplicate, and the error bars show the standard deviations of three consecutive measurements.

FIGS. 2C and 2D compares the values of water proton transverse relaxation rates R₂(¹H₂O) detected for LANTUS and BASAGLAR drug products with their corresponding simple counterfeits (i.e., 3 mL of saline in a corresponding pen). In FIGS. 2C and 2D, the R₂(¹H₂O) values for real insulin products differs from that of their corresponding drug containers (pens) filled with a 3 mL volume of sterile saline, which means a single R₂(¹H₂O) may be used to distinguish between them.

FIGS. 2E-2G compares the R₂(¹H₂O) values detected for NEUPOGEN, GRANIX, and NIVESTYM with their corresponding simple counterfeits (i.e., 1 mL of saline in a corresponding vial).

Similar to the results with insulin products, a comparison of R₂(¹H₂O) for filgrastim drug products shows detectable differences between the real biotherapeutics and a simple counterfeit in a similar vial, which means a single R₂(¹H₂O) may be used to distinguish between them.

In summary, a single R₂(¹H₂O) (univariate wNMR) can readily distinguish biotherapeutic products formulated as aqueous solutions from a simple counterfeit such as physiological saline.

c. Using Univariate wNMR to Detect Sophisticated Counterfeit Products Formulated as Solutions

Two sets of biotherapeutics were used to demonstrate that a single R₂(¹H₂O) (univariate wNMR) may detect sophisticated counterfeit biotherapeutics that are formulated as aqueous solutions. Each set of products contains one innovator biotherapeutic and its two biosimilars. In each set, the three products serve as sophisticated counterfeits for each other. Note that this is a very stringent test for counterfeit detection because biosimilars are recognized by the FDA to be highly similar to their innovator products.

All measurements were done noninvasively using the CPMG pulse sequence, at the same inter-pulse delay time τ (0.5 ms), at 5° C., in the probe cavity of our VT-NMR. All measurements were done in triplicate, and the error bars show the standard deviations of three consecutive measurements. For each of these products, 10 units per product from the same batch were analyzed, in prefilled pens for insulin and glass vials for filgrastim.

The first set is the innovator insulin product LANTUS and its two biosimilar products BASAGLAR, and insulin glargine-yfgn. In FIGS. 2H-2J, the R₂(¹H₂O) of each pen is the arithmetic mean of 3 consecutive measurements. Average R₂(¹H₂O) of each product (solid line) is the arithmetic mean of 30 R₂(¹H₂O) values, 3 measurements of each pen. Grey error band (dashed borders) is also calculated as a standard deviation of 30 R₂(¹H₂O) values, 3 measurements of each pen. In FIGS. 2H-2J, the values of R₂(¹H₂O) for the three insulin products show statistically significant differences from each other, indicating that a single R₂(¹H₂O) can distinguish an innovator product from its biosimilar products.

The second set is the innovator filgrastim product NEUPOGEN and its two biosimilar products, GRANIX and NIVESTYM. FIG. 2K-2M compares the values of R₂(¹H₂O) detected for 10 vials of each of the NEUPOGEN, GRANIX and NIVESTYM drug products. In FIGS. 2K-2M, the R₂(¹H₂O) of each vial is the arithmetic mean of 3 consecutive measurements. Average R₂(¹H₂O) of each product (solid line) is the arithmetic mean of 30 R₂(¹H₂O) values, 3 measurements of each vial. Grey error band (dashed borders) is also calculated as a standard deviation of 30 R₂(¹H₂O) values, 3 measurements of each vial. Similar to the case of insulin glargine pens, comparison of R₂(¹H₂O) for filgrastim drug products shows detectable differences between the real biotherapeutics and a complex counterfeit in a similar vial.

d. Using Multi-Variate wNMR to Detect Sophisticated Counterfeit Products Formulated as Solutions

Multi-variate wNMR may be used for detecting counterfeit pharmaceutical products formulated as solutions. For solution products, the most straightforward form of multi-variate wNMR is the τ-dispersion profile of R₂(¹H₂O), i.e., R₂(¹H₂O) measured at different τ values, with τ being an adjustable parameter in the CPMG pulse sequence used to measure R₂(¹H₂O). For solution products, their R₂(¹H₂O) values may be very close to each other in certain τ region but much more different from each other in other τ regions. This is the rationale for using multi-variate R₂(¹H₂O, τ) to differentiate solution counterfeits from the real solution products.

FIG. 2N shows the R₂(¹H₂O, τ) profiles for physiological saline, MENACTRA and TYPHIM VI. All measurements were done noninvasively using the CPMG pulse sequence with the inter-pulse delay τ varied from 0.5 ms to 10 ms with at 0.25 ms increments (˜40 measurements for each dispersion profile), taken at 5° C., in the probe cavity of VT-NMR. A measurement at a single τ-value takes ˜1 min, and total experiment duration is ˜55 min.

In FIG. 2N and the data in Table 2, τ-dispersion experiments result in unique dependencies of R₂(¹H₂O) vs. τ which allow for the detection of complex counterfeit non-adjuvanted vaccines. While at τ=0.5 ms, the differences between R₂(¹H₂O) is small (especially between MENACTRA and TYPHIM VI), while at τ=10 ms the differences between R₂(¹H₂O) is much more pronounced and can be used to detect the counterfeits with greater reliability. Therefore, using this observation, one might select a particular single τ-value of a given product for counterfeit detection with higher accuracy.

TABLE 2
Comparison of the R₂(¹H₂O) values at two different τ-values
for complex counterfeit non-adjuvanted vaccines.

| | R₂(¹H₂O), τ = | R₂(¹H₂O), τ = |
|---|---|---|
| Sample | 0.5 ms | 10 ms |
| Saline vial (0.5 mL) | 0.724 ± 0.002 | 1.506 ± 0.009 |
| MENACTRA vial (0.5 mL) | 0.680 ± 0.001 | 1.381 ± 0.004 |
| TYPHIM VI syringe (0.5 mL) | 0.671 ± 0.001 | 1.56 ± 0.002 |

The results in FIG. 2N and Table 2 show that if or when univariate wNMR has difficulty differentiating a product from its counterfeit, one can use multi-variate wNMR, such as R₂(¹H₂O, τ), to differentiate them. Further, multi-variate wNMR may help to optimize univariate wNMR such that the optimized univariate wNMR can differentiate the real product from the counterfeit, such as a single R₂(¹H₂O) measured at an optimized τ (e.g., 10 ms instead of 0.5 ms as in the current example).

FIG. 2O compares R₂(¹H₂O, τ) dispersion profiles for innovator/biosimilar products, NEUPOGEN/GRANIX/NIVESTYM. FIG. 2P compares R₂(¹H₂O, τ) dispersion profiles for GRANIX/SALINE pair, wherein saline serves as a simple counterfeit for GRANIX. It is clear that the multi-variate R₂(¹H₂O, τ) profile provides more discerning differentiation power than a univariate R₂(¹H₂O) at fixed τ.

### Example 3

### Examples for Detecting Substandard Pharmaceutical Products

Substandard products refer to authentic pharmaceutical products that do not meet release specifications. There are various types of substandard products as a result of manufacturing and handling errors. In this example, mock substandard products are generated by heating or freeze/thaw (F/T) stress, two of the most common types of handling errors that may result in substandard pharmaceutical products.

a. Detection of Substandard Pharmaceutical Products Damaged by Heat Stress Using Univariate wNMR

Most biologics are sensitive to heat and therefore require a cold chain for their distribution. In this example, wNMR is used to detect heat-damaged pharmaceutical products.

Two vaccines were analyzed, (a) ENGERIX-B, presented in a glass vial containing 1.0 mL of the vaccine, and formulated using the aluminum hydroxide adjuvant ALHYDROGEL (0.5 mg/mL of Al(III)), and (b) TDVAX, presented in a glass vial containing 0.5 mL of the vaccine, and formulated using the aluminum hydroxyphosphate adjuvant ADJU-PHOS (1.06 mg/mL of Al(III)). Unstressed products serve as the reference for comparison for the two vaccines. Six vials of each vaccine were analyzed: before stress (vials 1, 2, 3, 7, 8, 9), and after heat stress 55° C. for 24 hours (vials 1, 2, 3). The remaining 3 vials from each set (vials 7, 8, 9) served as unstressed controls and were kept at 4-5° C.

All measurements were done noninvasively using the CPMG pulse sequence, at the same interpulse delay time τ (0.5 ms), at 5° C., in the probe cavity of VT-NMR. All measurements were done in triplicate, and the error bars show the standard deviations of three consecutive measurements.

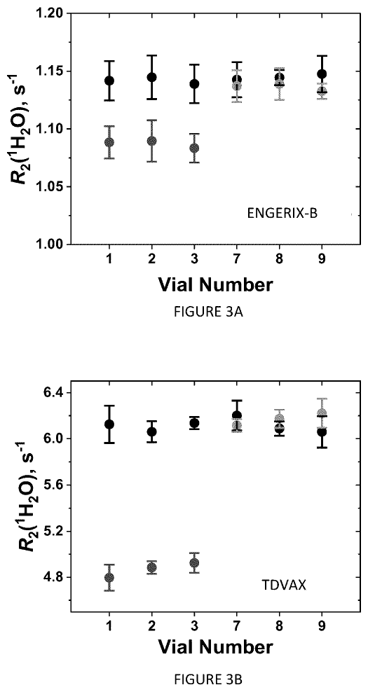

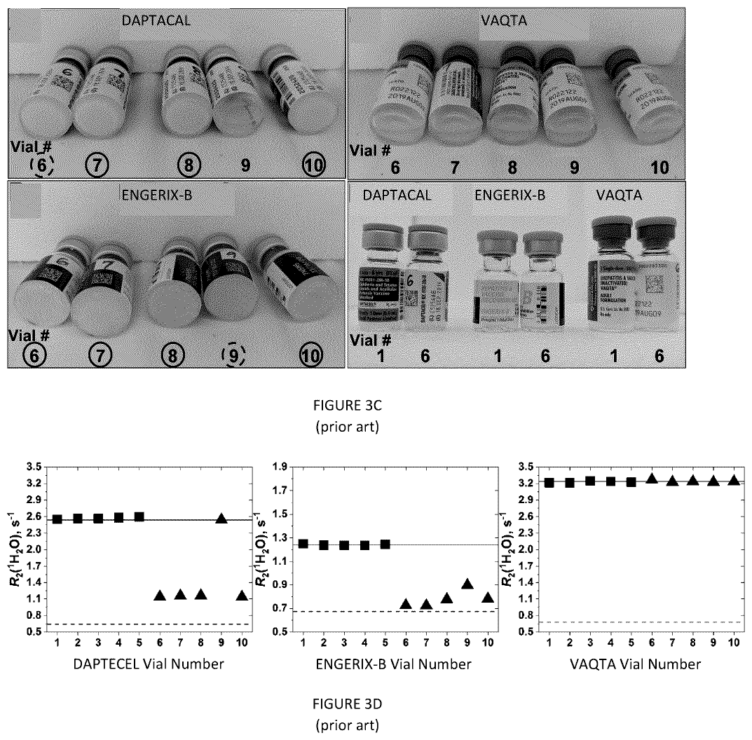

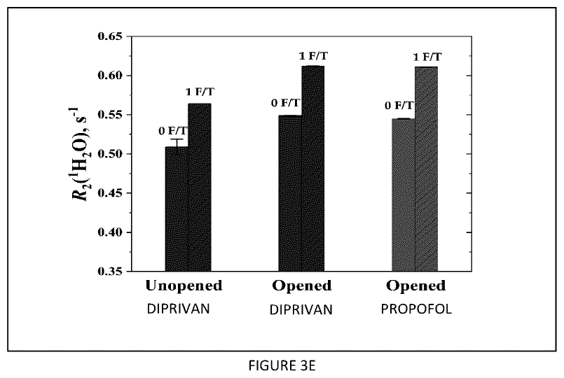

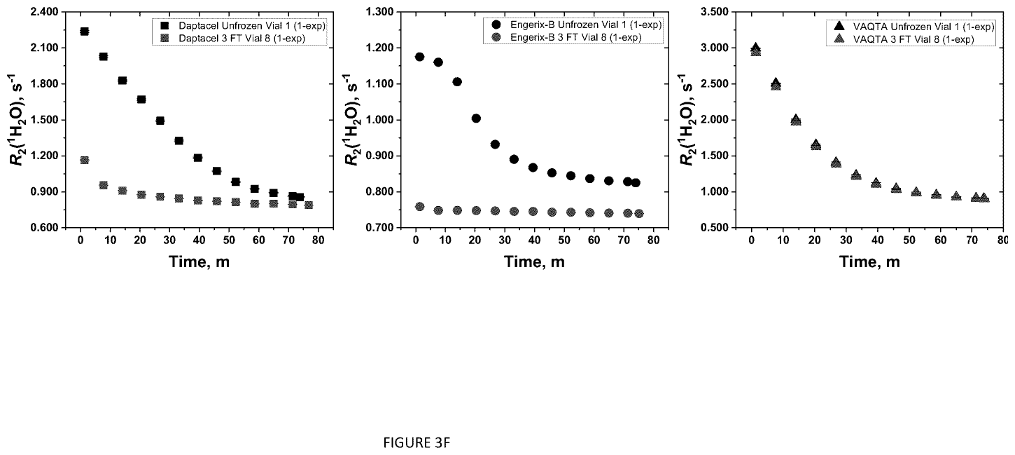

FIG. 3A compares the values of water proton transverse relaxation rates R₂(¹H₂O) detected for ENGERIX-B before and after heat stress together with unstressed control vials. As seen from FIG. 3A, heat stress results in a detectable decrease of R₂(¹H₂O), 0.06 s⁻¹, for vials 1-3 of ENGERIX-B, whereas unstressed control vials 7-9 demonstrate essentially unchanged R₂(¹H₂O) values compared to the pre-stress measurements.

An even larger difference between unstressed and heat-stressed samples was observed for TDVAX. FIG. 3B shows an almost 1.5 s⁻¹ drop in R₂(¹H₂O) value for stressed vials 1-3 compared to the pre-stress data. Again, similar to the above case of ENGERIX-B, the results for unstressed control vials 7-9 remained unchanged.

These results demonstrate the capability of univariate wNMR to detect pharmaceutical products that have been damaged by heat.

b. Detection of Substandard Vaccine Products Damaged by F/T-Induced Damage Using Univariate wNMR

Three aluminum-adjuvanted vaccines, DAPTACEL, ENGERIX-B and VAQTA, were subjected to F/T stress. Each vaccine contained Al³⁺ in quantities of 0.33 mg per dose/vial (0.66 mg/mL) for DAPTACEL as aluminum phosphate, 0.5 mg per dose/vial (0.5 mg/mL) for ENGERIX-B as aluminum hydroxide, and 0.45 mg per dose/vial (0.45 mg/mL) for VAQTA as amorphous aluminum hydroxyphosphate sulfate. Of the ten vials, vials #1-5 were kept at 5° C. to serve as controls while vials #6-10 were subjected to three cycles of the following sequence: −18° C. for 18 h followed by 5° C. for 2 h.

FIG. 3C shows photos of vials #6-10 of each product immediately after the third exposure to −18° C. Note that not all vials froze after being to −18° C. for 18 h. For example, vial #9 of DAPTACEL and vials #6-10 of VAQTA did not freeze after three exposures.

After each cycle, the R₂(¹H₂O) of all ten vials of each product in their fully suspended state was measured. The results are shown in FIG. 3D. It can be seen that vials that experienced actual freeze/thaw all have noticeably lower R₂(¹H₂O) values than vials that did not experience actual freeze/thaw. For example, although vial #9 of DAPTACEL and vials #6-10 of VAQTA each experienced F/T-stress (subzero temperatures) three times, they did not actually freeze and their R₂(¹H₂O) values do not differ from non-stressed vials of the same product, which were kept at 5° C.

The results show that univariate R₂(¹H₂O) can reliably detect vials of aluminum-adjuvanted vaccines that have experienced actual freeze/thaw instead of mere exposure to subzero temperatures.

c. Detection of Substandard Drug Products Damaged by F/T-Induced Damage Using Univariate wNMR

Two emulsion products, DIPRIVAN and PROPOFOL, were subjected to one F/T cycle of −30° C. for 16 h followed by room temperature overnight. The product vials were measured before and after the F/T cycle. FIG. 3E shows that after one F/T cycle, R₂(¹H₂O) increased significantly for both products.

d. Detecting F/T-Induced Damage Using Multi-Variate wNMR

Substandard pharmaceutical products may also be detected using multi-variate wNMR. This capability was demonstrated using F/T-damaged aluminum-adjuvanted vaccines. Note that F/T-damaged aluminum adjuvanted vaccines can be detected using univariate wNMR, as shown in the above sections, however the usefulness of multi-variate wNMR in detecting F/T-damaged products is significant. Sedimentation kinetics of aluminum-adjuvanted vaccines, i.e., R₂(¹H₂O, t) or Type II, served as the multi-variate wNMR for detecting F/T-induced damage.

Three aluminum-adjuvanted vaccines, DAPTACEL, ENGERIX-B and VAQTA, were subjected to three cycles of −18° C. for 18 h and 5° C. for 2 h. The sedimentation kinetics of one non-stressed vial (vial #1) and one stressed vial (vial #8) was monitored via R₂(¹H₂O). The stressed vial (vial #8) of DAPTACEL and ENGERIX-B froze after each F/T cycle while the stressed vial (vial #8) of VAQTA did not freeze after any of the three F/T cycles. FIG. 3F shows R₂(¹H₂O, t) of stressed and unstressed vials of each product.

R₂(¹H₂O, t) is clearly different for vials that experienced F/T versus vials that did not experience F/T. It is worth noting that the stressed vial (vial #8) of VAQTA did not experience any actual freeze/thaw in spite of being exposed to −18° C. The two vials of VAQTA, stressed and unstressed, show almost identical R₂(¹H₂O, t) profiles. The results show that R₂(¹H₂O, t) can reliably detect vaccine vials that have experienced actual freeze/thaw damage rather than mere exposure to subzero temperatures.

### Example 4

### Examples for Suspension Counterfeit Detection

Here, aluminum-adjuvanted vaccines illustrate that wNMR is useful to detect counterfeit pharmaceutical products formulated as suspensions.

Suspensions and emulsions have complex hydrodynamic behavior, which might complicate the very last step of product manufacturing, the fill-finish step. For example, alum particles tend to sediment in water, which may lead to uneven filling of vials from the batch.

a. Detecting Simple Counterfeit Suspensions Using Univariate wNMR

FIGS. 4A-4H below show the comparisons of water proton transverse relaxation rates, R₂(¹H₂O), of real vaccine products in their original vials or pre-filled syringes with the simple counterfeits (sterile 0.9% NaCl saline). All measurements were done noninvasively using the CPMG pulse sequence, at the same inter-pulse delay time τ (0.5 ms), at 5° C., in the probe cavity of VT-NMR. All measurements were done in triplicate, and the error bars show the standard deviations of three consecutive measurements.

In summary, univariate wNMR, in the form of a single R₂(¹H₂O) value measured per pharmaceutical product, can readily distinguish aluminum-adjuvanted vaccines from simple counterfeits such as physiological saline.

b. Detecting Sophisticated Counterfeit Vaccines Using Univariate wNMR

Table 3 lists a single R₂(¹H₂O) for eight aluminum adjuvanted vaccines. It can be seen that for any given pair of these eight vaccines, their R₂(¹H₂O) values differ by more than the measurement error, which means a single R₂(¹H₂O) may be used to distinguish between a pair of aluminum-adjuvanted vaccines.

TABLE 3
Ten vaccine measurement results.

| | | Antigen | Adjuvant | Volume | | R₂(¹H₂O) (s⁻¹) |
|---|---|---|---|---|---|---|
| No. | Brand Name | Type | (Al, mg/mL) | (mL) | Presentation | (CV) |
| 1 | DAPTACEL | toxoid | AP | 0.5 | vial | 2.239 ± 0.012 |
| | | | (0.66) | | | (0.54%) |
| 2 | ENGERIX-B | recombinant | AH | 1.0 | vial | 1.105 ± 0.005 |
| | | | (0.50) | | | (0.45%) |
| 3 | VAQTA | inactivated | AAHS | 1.0 | vial | 2.827 ± 0.023 |
| | | | (0.45) | | | (0.81%) |
| 4 | PREVNAR 13 | conjugate | AP | 0.5 | syringe | 0.971 ± 0.032 |
| | | | (0.25) | | | (3.30%) |
| 5 | BEXSERO | recombinant | AH | 0.5 | syringe | 1.737 ± 0.013 |
| | | | (1.038) | | | (0.75%) |
| 6 | INFANRIX | toxoid | AH | 0.5 | vial | 1.218 ± 0.031 |
| | | | (1.25) | | | (2.55%) |
| 7 | TDVAX | toxoid | AP | 0.5 | vial | 5.186 ± 0.084 |
| | | | (1.06) | | | (1.62%) |
| 8 | TENIVAC | toxoid | AP | 0.5 | vial | 2.056 ± 0.037 |
| | | | (0.66) | | | (1.80%) |

However, for some pairs, their R₂(¹H₂O), although statistically different, are close in values. For example, R₂(¹H₂O) values for DAPTACEL and TENIVAC are 2.239±0.012 s⁻¹ and 2.056±0.005 s⁻¹, respectively. Multi-variate wNMR was performed for selected pairs to determine if its possible to more readily distinguish sophisticated vaccines (and counterfeits) from one another.

b. Detecting Sophisticated Counterfeit Vaccines Using Type I Multi-Variate wNMR

In Type I multi-variate wNMR, R₂(¹H₂O) is measured at multiple τ-values, where τ is an adjustable parameter in the CPMG pulse sequence used to measure R₂(¹H₂O). In Type I measurements, R₂(¹H₂O, τ) is performed on fully settled suspension vaccines, noninvasively, in the original vial/syringe. Pairs of the vaccines with close values of R₂(¹H₂O at a single τ-value (0.5 ms) in the settled state were selected. In these multi-variate wNMR experiments, the CPMG pulse sequence inter-pulse delay, τ, was varied from 0.5 ms to 10 ms with a 0.25 ms increment (˜40 different τ-values per vaccine) at a set sample temperature of 5° C. in the probe cavity of a VT-NMR.

FIG. 4I shows the comparisons of the dependence of R₂(¹H₂O) vs. τ for two aluminum-adjuvanted vaccine products, DAPTACEL and TENIVAC. Note that both vaccines are presented in glass vials containing 0.5 mL of the vaccine, and both are formulated at the identical concentrations of aluminum hydroxyphosphate adjuvant, ADJU-PHOS, at 0.66 mg/mL of Al(III). As seen from FIG. 4I, much larger difference in R₂(¹H₂O) between these two vaccines in the fully settled state is observed at high τ-values (around 10 ms).

FIG. 4J shows a comparison of the dependence of water proton transverse relaxation rates R₂(¹H₂O) vs. τ for two aluminum-adjuvanted vaccine products, ENGERIX B and PREVNAR 13. ENGERIX B is presented in a glass vial containing 1.0 mL of the vaccine, and formulated using aluminum hydroxide adjuvant, ALHYDROGEL, at 0.5 mg/mL of Al(III), while PREVNAR 13® is presented in a glass needleless syringe containing 0.5 mL of the vaccine, and formulated using an aluminum hydroxyphosphate adjuvant, ADJU-PHOS, at 0.25 mg/mL of Al(III). The difference between ENGERIX B and PREVNAR 13 is visually apparent in the settled state.

FIG. 4K presents the comparative plots of the dependence of R₂(¹H₂O) vs. τ for two aluminum-adjuvanted vaccine products, BEXSERO and INFANRIX. Both vaccines are presented in glass syringes containing 0.5 mL of the vaccine, and both are formulated using an aluminum hydroxide adjuvant, ALHYDROGEL. However, the adjuvant concentrations are slightly different −1.04 mg/mL of Al(III) for BEXSERO, and ≤1.25 mg/mL of Al(III) for INFANRIX. In FIG. 4K, for BEXSERO and INFANRIX, the τ-dispersion profiles show significant differences for settled vaccines.

These results clearly demonstrate the fingerprinting potential of τ-dispersion profiles and confirm the capability of wNMR technology to differentiate between real and complex counterfeit vaccines.

c. Type II Multi-Variate wNMR: Sedimentation Kinetics

In Type II multi-variate wNMR, R₂(¹H₂O) is measured over time on (initially) a fully dispersed suspension at a single τ value (full dispersion is achieved by vigorous shaking of the vial or pre-filled syringe, as instructed by the package inserts for aluminum-adjuvanted vaccines). As the particles in the suspension settle, the R₂(¹H₂O) changes with time. R₂(¹H₂O, t) is the sedimentation kinetics profile of a suspension.

FIG. 4L shows the distinguishing power of Type II multi-variate wNMR of two aluminum-adjuvanted vaccines serving as complex counterfeits of one another, DAPTACEL and TENIVAC. Both vaccines are presented in sealed glass vials containing 0.5 mL of the vaccine, and both are formulated with the same concentrations of ADJU-PHOS adjuvant at 0.66 mg/mL of Al(III).

The sedimentation rate, k_{sed}, of DAPTACEL was 22.683±1.056 min⁻¹ compared to k_{sed} of TENIVAC of 9.819±0.416 min⁻¹, which are significantly different from each other, despite their identical adjuvant concentration. This is an illustration of how counterfeit suspension products could be distinguished from one another using Type II multi-variate wNMR.

d. Type III Multi-Variate wNMR: τ-Dispersion+Sedimentation Kinetics

In Type III multi-variate wNMR, the R₂(¹H₂O) is measured over time on fully dispersed suspensions. However, in contrast to Type II, where R₂(¹H₂O) is measured over time monitoring sedimentation kinetics at a single τ-value, in Type III, the R₂(¹H₂O) is measured over time at multiple τ-values. The data, R₂(¹H₂O, t, τ), forms a sophisticated fingerprint for a product.

The simplest Type III profile is R₂(¹H₂O) of a fully dispersed suspension measured over time at two alternating τ-values, where the R₂(¹H₂O) at multiple τ-values are collected during and throughout a single sedimentation process of a suspension product in an alternating pattern.

PREVNAR 13 and PREVNAR 20 are pneumococcal 13- and 20-valent conjugate vaccines, respectively, both containing 0.25 mg/mL of Al(III) as aluminum phosphate (ADJU-PHOS) adjuvant. Both vaccines are presented in pre-filled needless syringes containing 0.5 mL of a vaccine. Since these vaccines differ only by a number of antigens of S. pneumoniae serotypes—13 in PREVNAR 13 and 20 in PREVNAR 20—these two vaccines can serve as close counterfeits of each other.

The sedimentation kinetics of PREVNAR 13 and PREVNAR 20 was compared using the CPMG pulse sequence with monitoring at alternating τ-values −0.5 ms and 10 ms. Importantly, the sedimentation process was monitored with the syringes positioned tip-up in the NMR tube inside the probe of the VT-NMR. The total time of sedimentation kinetics monitoring was ˜24 hours. All measurements were performed at 4° C.

As seen from FIG. 4M, there is a notable difference between two vaccines of the sedimentation kinetics profiles at τ=10 ms, while at τ=0.5 ms the difference is less pronounced, though still could be observed at the initial portion of the sedimentation profiles. In sum, sedimentation kinetics at two inter-pulse delay τ values clearly show the capability to differentiate between two very similar vaccines.

FIG. 4N displays the data as a ratio of the R₂(¹H₂O) values at two τ values that were collected in an alternating fashion during the same sedimentation process of the vaccine. PREVNAR 13 and PREVNAR 20 have a different overall profile of R₂(¹H₂O, 10 ms τ)/R₂(¹H₂O, 0.5 ms τ) over the course of sedimentation. Ultimately, this data suggests that Type III multi-variate wNMR distinguishes between the two vaccines, which only differ by the number of antigens present.

In more sophisticated Type III multi-variate wNMR, R₂(¹H₂O) of a fully dispersed suspension is measured over time at multiple τ values. In the examples below, τ was varied from 0.5 ms to 10 ms at 0.25 ms steps. For aluminum-adjuvanted vaccines, all τ-dispersion measurements started with suspended drug products, noninvasively, in the original vial/syringe. Again, in these experiments, pairs of the vaccines with close values of R₂(¹H₂O) at single τ-value (0.5 ms) in settled state were selected. Measurement at a single τ-value takes ˜1 min, and total experiment duration is ˜55 min. In Type III experiments, multi-variate wNMR captures not only the dependence of R₂(¹H₂O, t), but also the dependence of R₂(¹H₂O, τ) synergistically providing a complex fingerprint of an individual vaccine formulation.

FIG. 4O shows the dependence of R₂(¹H₂O) vs. τ for two aluminum-adjuvanted vaccine products, DAPTACEL and TENIVAC taken during the sedimentation process. For the suspended state in FIG. 4O, τ-dispersion profiles demonstrate significant differences due to the combination of the effects of τ-variation and the sedimentation process of the suspended vaccines which occur during the τ-dispersion experiment. Of note, the sedimentation process results in the decrease of R₂(¹H₂O), while the incremental τ-increase leads to the larger R₂(¹H₂O) values. Therefore, FIG. 4O reflects the competition of these two processes.

FIG. 4P shows the comparisons of the dependence of R₂(¹H₂O) vs. τ for two aluminum-adjuvanted vaccine products, ENGERIX B and PREVNAR 13 taken during sedimentation process.

Remarkable differences between vaccine pairs could be seen when measured in the suspended states (FIG. 4P). The sedimentation process is much slower for PREVNAR 13, so it lags behind the R₂(¹H₂O) growth driven by the increasing τ-values, while ENGERIX B demonstrates a clear competition between sedimentation and τ-effects similar to the above case of DAPTACEL and TENIVAC (cf. FIGS. 4O and 4P).

FIG. 4Q presents the dependence of R₂(¹H₂O) vs. τ for two aluminum-adjuvanted vaccine products, BEXSERO and INFANRIX taken during sedimentation process. As seen from FIG. 4Q, for BEXSERO and INFANRIX, τ-dispersion profiles show significant differences in monitoring of the suspended vaccines. Note that BEXSERO sediments slowly, and thus does not show the characteristic drop/minimum of R₂(¹H₂O) associated with fast sedimentation observed for DAPTACEL and TENIVAC (FIG. 4O), ENGERIX B (FIG. 4P), and INFANRIX (FIG. 4Q).

These results clearly demonstrate the fingerprinting potential of Type III multi-variate wNMR and confirm the capability of wNMR technology to differentiate between real and complex counterfeit vaccines.

e. Other Types of Multi-Variate wNMR

If needed, other types of multi-variate wNMR profile may also be constructed, such as τ values may be scanned from 0.5 ms to 10 ms at 0.25 ms steps and then decrease from 1.5 ms to 0.5 ms at 0.25 ms steps. Such cycles could be repeated multiple times to obtain a more complex picture of the sedimentation vs. τ profiles which might be unique for different drug products.

Additional types of wNMR, R₁-R₂ (also called T₁-T₂) correlation profiles for all types of products (solutions, emulsions and suspensions), R₂/R₁ ratio over time for suspensions at a single τ or variable τ, may be used for counterfeit detection.

Although the invention has been variously disclosed herein with reference to illustrative embodiments and features, it will be appreciated that the embodiments and features described hereinabove are not intended to limit the invention, and that other variations, modifications and other embodiments will suggest themselves to those of ordinary skill in the art, based on the disclosure herein. The invention therefore is to be broadly construed, as encompassing all such variations, modifications and alternative embodiments within the spirit and scope of the claims hereafter set forth.

What is claimed is:

1. A method of using multi-variate NMR to identify a substandard or counterfeit product, said method comprising:
identifying a preferred inter-pulse delay (τ) value for a transverse relaxation rate of solvent R₂ measurement, by:
inserting a first vial comprising a product in a nuclear magnetic resonance (NMR) instrument, wherein the product in the first vial is not substandard or a counterfeit;
varying pulse sequence inter-pulse delay (τ) values from x ms to y ms in increments of z ms, wherein z could be any value, but <x and not >y, at a set temperature, and measuring the transverse relaxation rate of solvent R₂ at each τ value, thereby obtaining a first fingerprint for the product in the first vial;
inserting a second vial comprising a product suspected to be substandard or counterfeit in the NMR instrument;
varying the same pulse sequence inter-pulse delay (τ) values of x, y, and z, at the same set temperature, and measuring the transverse relaxation rate of solvent R₂ at each τ value, thereby obtaining a second fingerprint for the product in the second vial;
identifying the preferred τ value by identifying a τ value where |R₂ (first vial)−R₂ (second vial)| is the greatest between x ms and y ms,
wherein the transverse relaxation rate of solvent R₂ should be measured at the preferred τ value to identify a vial comprising a substandard or counterfeit of the product in the first vial.

2. The method of claim 1, wherein the solvent is water and the transverse relaxation rate of water R₂(¹H₂O) is measured.

3. The method of claim 1, wherein (a) x is 1 or less; (b) y is 10 or more; (c) z is less than x and y/z is 20 or greater; or (d) any combination of (a)-(c).

4. The method of claim 1, wherein the R₂ is measured without opening the first or second vials or otherwise accessing the contents of the first or second vials.

5. The method of claim 1, wherein the first fingerprint and the second fingerprint are obtained at substantially the same temperature, substantially the same magnetic field strength, or both.

6. The method of claim 1, further comprising measuring the transverse relaxation rate of solvent R₂ of a new vial in a lot comprising the second vial, at the preferred τ value, wherein the product in the new vial is suspected of being a substandard or counterfeit of the product in the first vial.

7. A method of using a sedimentation rate to identify a substandard or counterfeit product, said method comprising:
measuring a sedimentation rate of a product contained in a first vial using a nuclear magnetic resonance (NMR) instrument, wherein the product in the first vial is not substandard or a counterfeit;
measuring a sedimentation rate of a product contained in a second vial using the NMR instrument, wherein the product in the second vial is suspected to be substandard or counterfeit; and
comparing the sedimentation rate of the product in the first vial and the product in the second vial,
wherein a substandard or counterfeit product is identified when the sedimentation rate of the product in the second vial is statistically different than the sedimentation rate of the product in the first vial.

8. The method of claim 7, wherein the product of the first vial and the second vial is a dispersed suspension.

9. The method of claim 7, wherein the product of the first vial and the second vial comprises an aluminum adjuvant.

10. The method of claim 7, wherein method further comprises:
fully dispersing the product contained in the first vial, wherein the product is a suspension;
inserting the first vial in a nuclear magnetic resonance (NMR) instrument;
measuring a transverse relaxation rate of solvent R₂ at a single τ value over time t; and
determining the sedimentation rate of the product in the first vial using a sedimentation kinetics profile (R₂(solvent, t)) of the product.

11. The method of claim 7, wherein the method further comprises:
fully dispersing the product contained in the second vial, wherein the product is a suspension;
inserting the second vial in a nuclear magnetic resonance (NMR) instrument;
measuring a transverse relaxation rate of solvent R₂ at a single τ value over time t; and
determining the sedimentation rate of the product in the second vial using a sedimentation kinetics profile (R₂(solvent, t)) of the product.

12. The method of claim 7, wherein the solvent is water and the transverse relaxation rate of water R₂(¹H₂O) is measured.

13. The method of claim 7, wherein the sedimentation rate is determined without opening the vial containing the first or second product or otherwise accessing the contents of said vials.

14. The method of claim 7, wherein the sedimentations rates are obtained at substantially the same temperature, substantially the same magnetic field strength, or both.

15. A method of identifying a substandard or counterfeit product, said method comprising:
inserting a first vial comprising a product in a nuclear magnetic resonance (NMR) instrument, wherein the product in the first vial is not substandard or a counterfeit;
measuring transverse relaxation rate of solvent R₂ over time at multiple τ-values of a fully dispersed product in said first vial, wherein the product is a suspension, and wherein the transverse relaxation rate of solvent R₂ at multiple τ-values is collected throughout a sedimentation process of the product in the first vial;
inserting a second vial comprising a product in the NMR instrument, wherein the product in the second vial is suspected to be substandard or a counterfeit of the product in the first vial;
measuring transverse relaxation rate of solvent R₂ over time at multiple τ-values of a fully dispersed product in said second vial, wherein the product is a suspension, and wherein the transverse relaxation rate of solvent R₂ at multiple τ-values is collected throughout a sedimentation process of the product in the second vial; and
plotting the transverse relaxation rate of solvent R₂ as a function of τ for both the first and second vial to obtain a first fingerprint corresponding to the first vial and a second fingerprint corresponding to the second vial, respectively,
wherein if the first fingerprint and the second fingerprint are not substantially identical, the product in the second vial is a substandard or counterfeit of the product in the first vial.

16. The method of claim 15, wherein the solvent is water and the transverse relaxation rate of water R₂(¹H₂O) is measured.

17. The method of claim 15, wherein the multiple τ-values correspond to pulse sequence inter-pulse delay (τ) values from x ms to y ms in increments of z ms, wherein z could be any value, but <x and not >y, at a set temperature.

18. The method of claim 15, wherein (a) x is 1 or less; (b) y is 10 or more; (c) z is less than x and y/z is 20 or greater; or (d) some combination of (a)-(c).

19. The method of claim 15, wherein the R₂ is measured without opening the first or second vials or otherwise accessing the contents of the first or second vials.

20. The method of claim 15, wherein the first fingerprint and the second fingerprint are obtained at substantially the same temperature, substantially the same magnetic field strength, or both.
